(19) United States
(12) Patent Application Publication
(10) Pub. No.: US 2026/0344020 A1
(43) Pub. Date: Oct. 29, 2026

(54) SEMICONDUCTOR DEVICE AND SEMICONDUCTOR MODULE

(71) Applicant: FUJI ELECTRIC CO., LTD., Kanagawa (JP)

(72) Inventors: Motoyoshi KUBOUCHI, Matsumoto-city (JP); Soichi YOSHIDA, Matsumoto-city (JP); Tatsuya HASHIMOTO, Azumino-city (JP)

(21) Appl. No.: 19/714,620

(22) Filed: Jun. 21, 2026

Related U.S. Application Data
(63) Continuation of application No. PCT/JP2025/023124, filed on Jun. 26, 2025.

(30) Foreign Application Priority Data
Jul. 2, 2024 (JP) 2024-107002

(51) Int. Cl. H10D 84/00; H10D 8/00; H10D 12/00; H10D 62/10; H10D 62/53; H10D 62/60; H10D 80/30; H10W 40/20; H10W 40/22

(52) U.S. Cl. CPC H10D 84/161; H10D 8/422; H10D 12/481; H10D 62/126; H10D 62/53; H10D 62/60; H10D 80/30; H10W 40/226; H10W 40/233; H10W 40/242

(57) ABSTRACT

Provided is a semiconductor device comprising a first active portion having a plurality of transistor portions and a plurality of diode portions alternately arranged in an arrangement direction. Provided is a semiconductor device, wherein the first active portion has, in the arrangement direction, a first end portion and a second end portion on an opposite side to the first end portion, the plurality of diode portions include a first diode portion provided closest to the first end portion and a second diode portion provided closest to the second end portion, the plurality of transistor portions include a first transistor portion provided closest to the first end portion and a second transistor portion provided closest to the second end portion, and the first diode portion is provided closer to the first end portion side than the first transistor portion.

### BACKGROUND

### 1. Technical Field

The present invention relates to a semiconductor device and a semiconductor module.

### 2. Related Art

Conventionally, in a semiconductor device in which a transistor portion such as an insulated gate bipolar transistor (IGBT) and a diode portion are formed on a same substrate, a technology is known in which a particle beam such as helium ions is irradiated to a predetermined depth position of a semiconductor substrate to provide a lifetime control region including a lifetime killer (for example, Patent Document 1).

### Related Art Document

### Patent Document

Patent Document 1: Japanese Patent Application Publication No. 2017-135339

### BRIEF DESCRIPTION OF THE DRAWINGS

FIG. 1 illustrates an example of a top view of a semiconductor device 100.

FIG. 2 is a top view in which an example of a region A of FIG. 1 is enlarged.

FIG. 3A illustrates an a-a cross section of FIG. 2.

FIG. 3B illustrates a different example of the a-a cross section of FIG. 2.

FIG. 3C illustrates a different example of the a-a cross section of FIG. 2.

FIG. 3D is a top view in which a different example of the region A of FIG. 1 is enlarged.

FIG. 3E illustrates a different example of the a-a cross section of FIG. 2.

FIG. 3F is a top view in which a different example of the region A of FIG. 1 is enlarged.

FIG. 3G illustrates a different example of the a-a cross section of FIG. 2.

FIG. 4 is a top view illustrating an example of an arrangement of transistor portions 70 and diode portions 80 in a first active portion 260 according to a comparative example.

FIG. 5A is a top view illustrating an example of an arrangement of transistor portions 70 and diode portions 80 in a first active portion 160.

FIG. 5B is a top view illustrating another example of the arrangement of the transistor portions 70 and the diode portions 80 in the first active portion 160.

FIG. 5C is a modification example of the arrangement of the transistor portions 70 and the diode portions 80 illustrated in FIG. 5B.

FIG. 5D is a modification example of the arrangement of the transistor portions 70 and the diode portions 80 illustrated in FIG. 5B.

FIG. 6 illustrates another example of an upper surface of the semiconductor device 100.

FIG. 7A is a top view illustrating an example of an arrangement of transistor portions 70 and diode portions 80 in the first active portion 160 and the second active portion 161.

FIG. 7B is a top view illustrating another example of the arrangement of the transistor portions 70 and the diode portions 80 in the first active portion 160 and the second active portion 161.

FIG. 8 is a top view in which an example of a region B of FIG. 1 is enlarged.

FIG. 9 illustrates a c-c cross section of FIG. 8.

FIG. 10A illustrates an example of a top view of a semiconductor module 1000 according to an embodiment.

FIG. 10B illustrates an example of an f-f cross section in FIG. 10A.

FIG. 10C is an example of a bottom view of the semiconductor module 1000.

FIG. 10D illustrates an example of a g-g cross section in FIG. 10C.

FIG. 10E is a schematic diagram illustrating a placement of the semiconductor device 100 in the semiconductor module 1000.

FIG. 10F is a schematic diagram illustrating another example of the placement of the semiconductor device 100 in the semiconductor module 1000.

FIG. 10G is a schematic diagram illustrating another example of the placement of the semiconductor device 100 in the semiconductor module 1000.

FIG. 10H is a schematic diagram illustrating another example of placement of the semiconductor device 100 in the semiconductor module 1000.

FIG. 10I is a schematic diagram illustrating another example of placement of the semiconductor device 100 in the semiconductor module 1000.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as an "upper" side, and another side is referred to as a "lower" side. Of two principal surfaces of a substrate, a layer, or another member, one surface is referred to as a front surface, and another surface is referred to as a back surface. “Upper” and “lower” directions are not limited to a direction of gravity or a direction when a semiconductor device is mounted.

In the present specification, technical matters may be described using orthogonal coordinate axes consisting of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a -Z axis direction are directions opposite to each other. When the Z axis direction is described without describing the signs, it means that the direction is parallel to the +Z axis and the -Z axis.

In the present specification, orthogonal axes parallel to the front surface and the back surface of the semiconductor substrate are referred to as the X axis and the Y axis. In addition, the axis perpendicular to the front surface and the back surface of the semiconductor substrate is defined as a Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

A region from a center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

When a term such as “same” or “equal” is used in the present specification, it may encompass a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

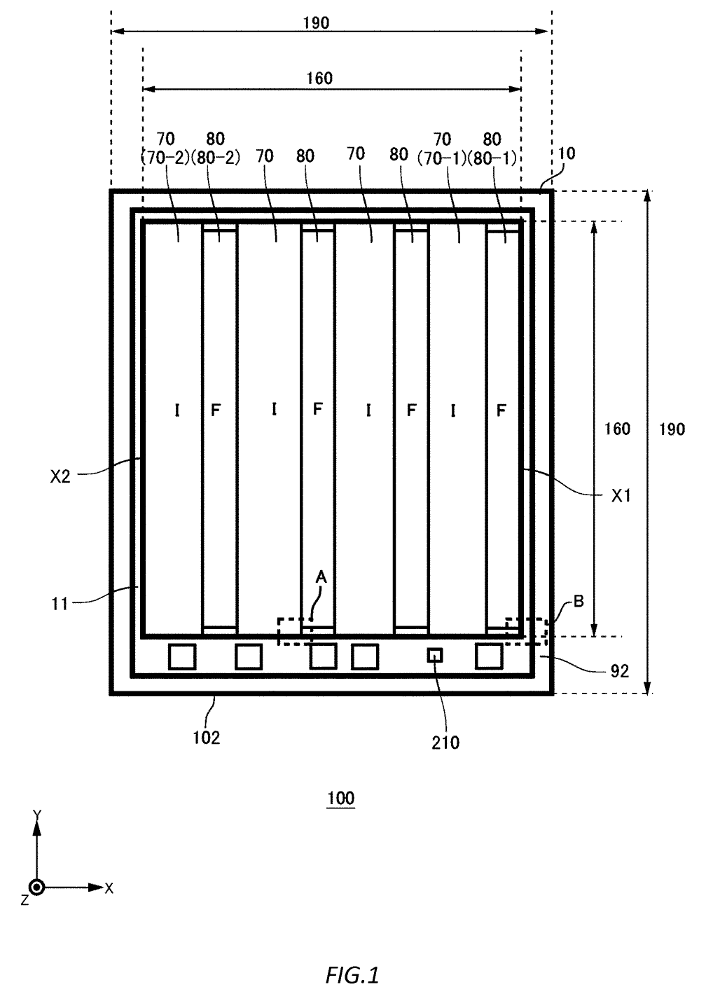

FIG. 1 illustrates an example of a top view of a semiconductor device 100. FIG. 1 shows positions at which respective members are projected onto a front surface of a semiconductor substrate 10. FIG. 1 shows merely some members of the semiconductor device 100, and omits illustrations of some members.

The semiconductor device 100 includes the semiconductor substrate 10. The semiconductor substrate 10 has an end side 102 in a top view. When merely referred to as the top view in the present specification, it means that the semiconductor substrate 10 is viewed from a front surface side. The semiconductor substrate 10 of the present example has two sets of end sides 102 opposite to each other in a top view. In FIG. 1, the X axis and the Y axis are parallel to any of the end sides 102. In addition, the Z axis is perpendicular to the front surface of the semiconductor substrate 10.

The semiconductor substrate 10 has a first active portion 160 and an outer peripheral region 190. The first active portion 160 is a region in which a main current flows in the depth direction between the front surface and the back surface of the semiconductor substrate 10 when the semiconductor device 100 operates. An emitter electrode is provided above the first active portion 160, but is omitted in FIG. 1.

The first active portion 160 has, at the front surface of the semiconductor substrate 10, a first end portion X1 and a second end portion X2 on an opposite side to the first end portion X1 in a predetermined element arrangement direction (the X axis direction in the present specification). Here, the first end portion X1 is defined as a positive side in the X axis direction and the second end portion X2 is defined as a negative side in the X axis direction, but the reverse may also be the case. In the first active portion 160, a transistor portion 70 including a transistor element such as an IGBT and a diode portion 80 including a diode element which is the freewheeling diode (FWD) are provided. In the example of FIG. 1, a plurality of transistor portions 70 and a plurality of diode portions 80 are alternately disposed in stripes along the X axis direction.

In FIG. 1, a region where each of the transistor portions 70 is disposed is indicated by a symbol "I", and a region where each of the diode portions 80 is disposed is indicated by a symbol "F". In the present specification, a direction perpendicular to the element arrangement direction in a top view may be referred to as an element extending direction (the Y axis direction in the present specification). The transistor portion 70 and the diode portion 80 may each have a longitudinal direction in a predetermined trench extending direction. In other words, the length of each of the transistor portions 70 in the Y axis direction is larger than the width in the X axis direction. Similarly, the length of each of the diode portions 80 in the Y axis direction is larger than the width in the X axis direction. Among the plurality of diode portions 80, the diode portion 80 provided closest to the first end portion X1 is referred to as a first diode portion 80-1, and the diode portion 80 provided closest to the second end portion X2 is referred to as a second diode portion 80-2. Among the plurality of transistor portions 70, the transistor portion 70 provided closest to the first end portion X1 is referred to as a first transistor portion 70-1, and the transistor portion 70 provided closest to the second end portion X2 is referred to as a second transistor portion 70-2.

A width of the transistor portion 70 in the X axis direction is larger than a width of the diode portion 80 in the X axis direction. In addition, the width of the transistor portion 70 in the X axis direction may be the same as the width of the diode portion 80 in the X axis direction. The element extending direction of the transistor portion 70 and the diode portion 80 and the trench extending direction of each trench portion may be the same. The element arrangement direction of the transistor portion 70 and the diode portion 80 and a trench arrangement direction of each trench portion described later may be the same.

Each of the diode portions 80 includes a cathode region of an N+ type in a region in contact with the back surface of the semiconductor substrate 10. In the present specification, a region where the cathode region is provided is referred to as the diode portion 80. In other words, the diode portion 80 is a region that overlaps with the cathode region in a top view. On the back surface of the semiconductor substrate 10, a collector region of a P+ type may be provided in a region other than the cathode region. In the present specification, the diode portion 80 may also include an extension region where the diode portion 80 extends to a gate runner described later in the Y axis direction. The collector region is provided on a lower surface of the extension region.

The transistor portion 70 has the collector region of the P+ type in a region in contact with the back surface of the semiconductor substrate 10. In addition, in the transistor portion 70, gate structures each having an emitter region of the N+ type, a base region of a P- type, a gate conductive portion, and a gate dielectric film are periodically disposed on the front surface side of the semiconductor substrate 10.

The semiconductor device 100 includes the outer peripheral region 190 disposed between the first active portion 160 and the end side 102 of the semiconductor substrate 10 in a top view. In the outer peripheral region 190 of the present example, a well region 11 is provided surrounding the first active portion 160 in a top view. In a top view, a region surrounded by the well region 11 may be defined as the first active portion 160, and a region extending from the well region 11 toward the end side 102 side may be defined as the outer peripheral region 190.

An outer peripheral gate runner 47 may be disposed above the semiconductor substrate 10. The outer peripheral gate runner 47 of the present example may be disposed above the well region 11. The outer peripheral gate runner 47 is electrically connected to the gate conductive portion provided inside a gate trench portion with the gate dielectric film interposed therebetween.

The outer peripheral region 190 of the present example surrounds the first active portion 160 in a top view. The outer peripheral region 190 includes an edge termination region. The edge termination region reduces electric field strength on the front surface side of the semiconductor substrate 10.

The outer peripheral region 190 of the present example has one or more auxiliary pads provided above the semiconductor substrate 10. As an example, the semiconductor device 100 has auxiliary pads such as an anode pad, a cathode pad, and a current detection pad. Each auxiliary pad may be provided above the well region 11. Each auxiliary pad may be connected to an external circuit via wiring such as a wire. In FIG. 1, an outline of each auxiliary pad is drawn to show a boundary thereof with a protective film surrounding the auxiliary pad, but exposed portions of other protective films are omitted, and description of the protective film is also omitted in the following explanatory drawings.

The outer peripheral region 190 of the present example may have a current sense portion 210. The current sense portion 210 detects a current flowing through the transistor portion 70. The current sense portion 210 may be provided inside the well region 11. The outer peripheral region 190 may further have a temperature sense portion which is a PN junction diode formed of polysilicon or the like. The temperature sense portion may be provided above the well region 11.

The outer peripheral region 190 of the present example may have a guard ring 92 as the edge termination region. The guard ring 92 is a region of the P type in contact with the front surface of the semiconductor substrate 10. Note that the edge termination region of the present example has a plurality of guard rings 92, but in FIG. 1, they are omitted and only one guard ring 92 is illustrated. By providing a plurality of guard rings 92, a depletion layer on an upper surface side of the first active portion 160 can be extended outward, and a breakdown voltage of the semiconductor device 100 can be improved. The edge termination region may further include at least one of a field plate or a RESURF annularly provided surrounding the first active portion 160.

In the present specification, “inner side” refers to a center side of the semiconductor substrate 10 in a top view, and “outer side” refers to the end side 102 side of the semiconductor substrate 10 in a top view.

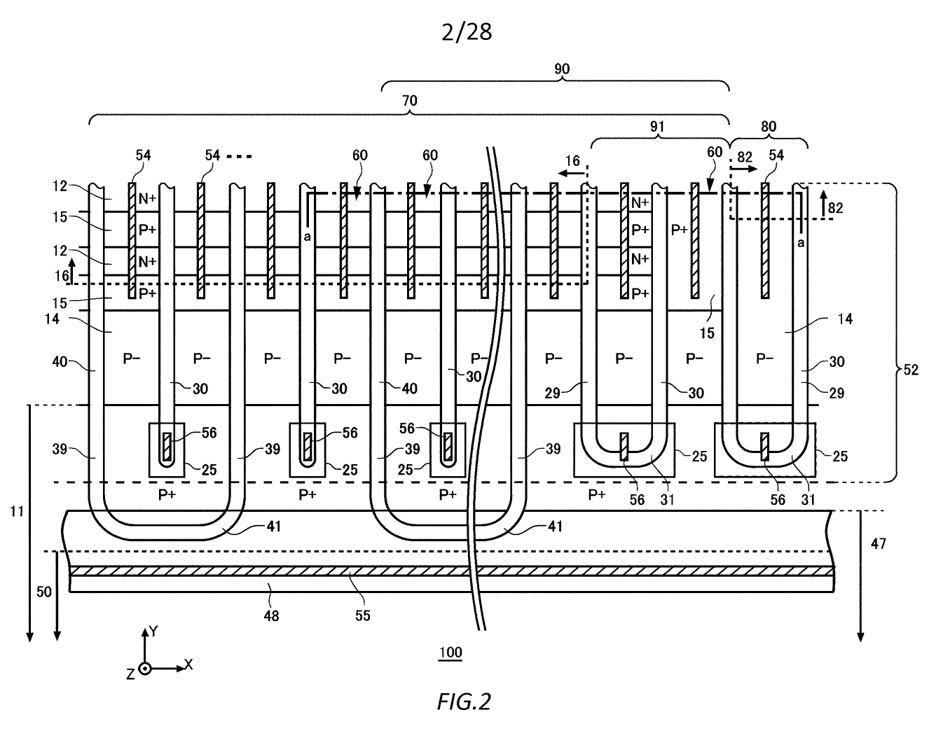

FIG. 2 is a top view in which an example of a region A of FIG. 1 is enlarged. The semiconductor device 100 includes a semiconductor substrate having the transistor portion 70 including a transistor element such as an IGBT and the diode portion 80 including a diode element such as a freewheeling diode (FWD).

The semiconductor device 100 of the present example includes a gate trench portion 40, a dummy trench portion 30, the well region 11, an emitter region 12, a base region 14, and a contact region 15 which are provided on the front surface of the semiconductor substrate 10. The gate trench portion 40 and the dummy trench portion 30 are each an example of a trench portion.

In addition, the semiconductor device 100 of the present example includes a gate metal layer 50 and an emitter electrode 52 provided above the front surface of the semiconductor substrate 10. The gate metal layer 50 and the emitter electrode 52 are provided separately from each other. The gate metal layer 50 and the emitter electrode 52 are electrically insulated from each other. An interlayer dielectric film is provided between the gate metal layer 50 and the emitter electrode 52, and the front surface of the semiconductor substrate 10, but is omitted in FIG. 2. In the interlayer dielectric film of the present example, contact holes 54, 55, and 56 are provided penetrating through the interlayer dielectric film. In FIG. 2, each contact hole is hatched with diagonal lines.

The emitter electrode 52 is provided above the gate trench portion 40, the dummy trench portion 30, the well region 11, the emitter region 12, the base region 14, and the contact region 15. The emitter electrode 52 is electrically connected, through the contact holes 54, to the emitter region 12, the base region 14, and the contact region 15 on the front surface of the semiconductor substrate 10.

In addition, the emitter electrode 52 is connected, through a contact hole 56, to a dummy conductive portion in the dummy trench portion 30. A connection portion 25 formed of a conductive material such as polysilicon doped with an impurity may be provided between the emitter electrode 52 and the dummy conductive portion. The connection portion 25 is provided at the front surface of the semiconductor substrate 10 with dielectric films, such as the interlayer dielectric film and a dummy dielectric film of the dummy trench portion 30, interposed therebetween. The dummy conductive portion and the emitter electrode 52 may be connected to each other by using the contact hole 56 provided above the dummy conductive portion, instead of providing the connection portion 25.

The gate metal layer 50 is electrically connected, through a contact hole 55, to a semiconductor gate runner 48. The gate metal layer 50 and the semiconductor gate runner 48 integrally constitute the outer peripheral gate runner 47. The gate metal layer 50 and the semiconductor gate runner 48 need not both be provided, or only one of them may be provided, in part or all of the region.

The semiconductor gate runner 48 and the emitter electrode 52 are electrically separated from each other by an insulator such as an interlayer dielectric film and an oxide film. The semiconductor gate runner 48 is provided at the front surface of the semiconductor substrate 10 with dielectric films, such as the interlayer dielectric film and the gate dielectric film of the gate trench portion 40, interposed therebetween. The semiconductor gate runner 48 of the present example is provided from below the contact hole 55 to a tip portion of the gate trench portion 40. At the tip portion of the gate trench portion 40, the gate conductive portion is exposed on the front surface of the semiconductor substrate 10 and is connected to the semiconductor gate runner 48.

The semiconductor gate runner 48 may be formed of polysilicon or the like doped with an impurity. The semiconductor gate runner 48 is connected to the gate conductive portion in the gate trench portion 40 at the front surface of the semiconductor substrate 10. The semiconductor gate runner 48 is not electrically connected to the dummy conductive portion in the dummy trench portion 30 and the emitter electrode 52. The gate conductive portion and the gate metal layer 50 may be connected to each other by using the contact hole 55 provided above the gate conductive portion, instead of providing the semiconductor gate runner 48. On the other hand, the gate metal layer 50 need not be provided.

The gate metal layer 50 and the emitter electrode 52 are formed of a conductive material containing a metal. For example, the gate metal layer 50 and the emitter electrode 52 are formed of aluminum or an aluminum-silicon alloy. The gate metal layer 50 and the emitter electrode 52 may have a barrier metal formed of titanium, a titanium compound, or the like under a region formed of aluminum or the like.

The emitter electrode 52 may have a plug formed of tungsten or the like in a contact hole 54. The plug may be formed by forming the barrier metal on a side in contact with the semiconductor substrate 10 in the contact hole 54 and embedding tungsten so as to be in contact with the barrier metal.

The plug may be in contact with the contact region 15 or the base region 14 below the contact hole 54. Alternatively, a plug region of a P++ type having a higher doping concentration than the contact region 15 may be provided below the contact hole 54 in which the plug is provided. The plug region can improve contact resistance between the barrier metal and the contact region 15.

By the plug region improving the contact resistance, latch-up tolerance is improved in operation of the transistor portion 70. On the other hand, in operation of the diode portion 80, conduction loss can be suppressed.

The well region 11 extends from the outer peripheral gate runner 47 and is provided annularly in a top view. The well region 11 also extends toward the first active portion 160 located on an inner side of the outer peripheral gate runner 47 with a predetermined width in the Y axis direction, and is provided annularly in a top view. The well region 11 of the present example is provided in a range separated toward the outer peripheral gate runner 47 from an end portion of the contact hole 54 in the Y axis direction. The well region 11 is a region of a second conductivity type having a higher doping concentration than the base region 14. A doping concentration of the well region 11 may be the same as a doping concentration of the contact region 15, or may be lower than this. The outer peripheral gate runner 47 is electrically insulated from the well region 11.

The base region 14 of the present example is of a P- type, and the well region 11 is of the P+ type. In addition, the well region 11 is formed from the front surface of the semiconductor substrate to a position deeper than a lower end of the base region 14. The base region 14 is provided in contact with the well region 11 in each of the transistor portion 70 and the diode portion 80. The well region 11 is electrically connected to the emitter electrode 52.

Each of the transistor portion 70 and the diode portion 80 has a plurality of trench portions arranged in the trench arrangement direction (X axis direction). In the transistor portion 70 of the present example, one or more gate trench portions 40 and one or more dummy trench portions 30 are alternately provided along the X axis direction. In the diode portion 80 of the present example, a plurality of dummy trench portions 30 are provided along the X axis direction.

The gate trench portion 40 of the present example may have two extending portions 39 (portions of the trench that are linear along the Y axis direction) extending along the trench extending direction (Y axis direction) perpendicular to the trench arrangement direction, and a connecting portion 41 connecting the two extending portions 39.

At least a part of the connecting portion 41 may be provided in a curved shape in a top view. The connecting portion 41 connects end portions of the two extending portions 39 in the Y axis direction to the outer peripheral gate runner 47, thereby functioning as a gate electrode for the gate trench portion 40. On the other hand, by making the connecting portion 41 curved, electric field strength at the end portions can be reduced as compared with a case where the gate trench portion 40 is completed at the extending portions 39.

In the transistor portion 70, the dummy trench portion 30 is provided between the respective extending portions 39 of the gate trench portion 40. In the example of FIG. 2, one dummy trench portion 30 is provided between the respective extending portions 39; however, two dummy trench portions 30 may be provided, or more than two dummy trench portions 30 may be provided.

In addition, between the respective extending portions 39, the dummy trench portion 30 need not be provided, and the gate trench portion 40 may be provided. With such a structure, an electron current from the emitter region 12 can be increased, and thus an on-voltage is reduced.

The dummy trench portion 30 may have a linear shape extending in the trench extending direction, and may have extending portions 29 and a connecting portion 31 similarly to the gate trench portion 40. In the semiconductor device 100 illustrated in FIG. 2, only dummy trench portions 30 having connecting portions 31 are arranged; however, in another example, the semiconductor device 100 may include a linear dummy trench portion 30 having no connecting portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, at the end portions of each trench portion in the Y axis direction, a bottom portion of each trench portion in the depth direction (positive side in the Z axis direction) is covered with the well region 11. With this configuration, electric field strength on the bottom portion of each trench portion can be reduced.

A mesa portion 60 is provided between the respective trench portions in the trench arrangement direction. The mesa portion 60 refers to a region sandwiched between the trench portions inside the semiconductor substrate 10. As an example, a depth position of the mesa portion 60 is from the front surface of the semiconductor substrate 10 to lower ends of the trench portions.

The mesa portion 60 of the present example is sandwiched between adjacent trench portions in the X axis direction, and is provided, on the front surface of the semiconductor substrate 10, extending in the Y axis direction along the trenches.

Each mesa portion 60 is provided with the base region 14. Each mesa portion 60 may be provided with at least one of the emitter region 12 of a first conductivity type or the contact region 15 of the second conductivity type in a region sandwiched between base regions 14 in a top view. The emitter region 12 of the present example is of the N+ type, and the contact region 15 is of the P+ type. The emitter region 12 and the contact region 15 may be provided between the base region 14 and the front surface of the semiconductor substrate 10 in the depth direction.

The mesa portion 60 of the transistor portion 70 has the emitter region 12 exposed on the front surface of the semiconductor substrate 10. The emitter region 12 is provided in contact with the gate trench portion 40. In the mesa portion 60 in contact with the gate trench portion 40, the contact region 15 exposed on the front surface of the semiconductor substrate 10 is provided.

Each of the contact region 15 and the emitter region 12 in the mesa portion 60 is provided from one trench portion to another trench portion in the X axis direction. As an example, the contact region 15 and the emitter region 12 of the mesa portion 60 are alternately disposed along the Y axis direction.

In another example, the contact region 15 and the emitter region 12 of the mesa portion 60 may be provided in stripes along the Y axis direction. For example, the emitter region 12 is provided in a region in contact with the trench portion, and the contact region 15 is provided in a region sandwiched between emitter regions 12.

No emitter region 12 is provided in the mesa portion 60 of the diode portion 80. The base region 14 may be provided on an upper surface of the mesa portion 60 of the diode portion 80. The base region 14 may be disposed over the entirety of the mesa portion 60 of the diode portion 80.

The contact hole 54 is provided above each mesa portion. The contact hole 54 is disposed in a region sandwiched by base regions 14 in the Y axis direction. The contact hole 54 of the present example is provided above each of the contact region 15, the base region 14, and the emitter region 12. The contact hole 54 may be disposed at the middle of the mesa portion in the X axis direction.

In the diode portion 80, a cathode region 82 of the N+ type is provided in a region in direct contact with the back surface of the semiconductor substrate 10. On the back surface of the semiconductor substrate 10, a collector region 22 of the P+ type may be provided in a region where no cathode region 82 is provided. In FIG. 2, a boundary between the cathode region 82 and the collector region 22 is indicated by a dotted line.

The cathode region 82 is disposed away from the well region 11 in the Y axis direction. Accordingly, by ensuring a distance between the cathode region 82 and a region of the P type (the well region 11) that has a relatively high doping concentration and is formed to a deep position, hole injection from the well region 11 can be suppressed, and therefore reverse recovery loss can be reduced. An end portion in the Y axis direction of the cathode region 82 of the present example is disposed farther away from the well region 11 than an end portion in the Y axis direction of the contact hole 54. In another example, the end portion in the Y axis direction of the cathode region 82 may be disposed between the well region 11 and the contact hole 54.

The transistor portion 70 has a boundary region 91 on an adjacent diode portion 80 side. The boundary region 91 is a region having a different configuration from those of the other transistor portions 70, so as not to cause structural and characteristic problems in a region adjacent to the diode portion 80. The boundary region 91 includes a plurality of mesa portions 60. In FIG. 2, the boundary region 91 includes two mesa portions 60, but may be composed of one mesa portion 60, or may include more than two mesa portions 60. In the boundary region 91, the dummy trench portion 30 may be provided, and the gate trench portion 40 need not be provided. In the mesa portion 60 closest to the diode portion 80 side in the boundary region 91, the emitter region 12 need not be provided. Note that the boundary region 91 need not be provided.

In addition, the transistor portion 70 has a transition region 90 on an adjacent diode portion 80 side. The transition region 90 may include, at a portion thereof closest to the diode portion 80 side, the above-described boundary region 91. The transition region 90 includes a plurality of mesa portions 60. Being close to the diode portion 80, the transition region 90 is a region that affects characteristics of the diode portion 80. In consideration of an influence on the diode portion 80, a configuration and characteristics may be different from those of the transistor portion 70 that is not the transition region 90. A configuration example of the transition region 90 will be described later.

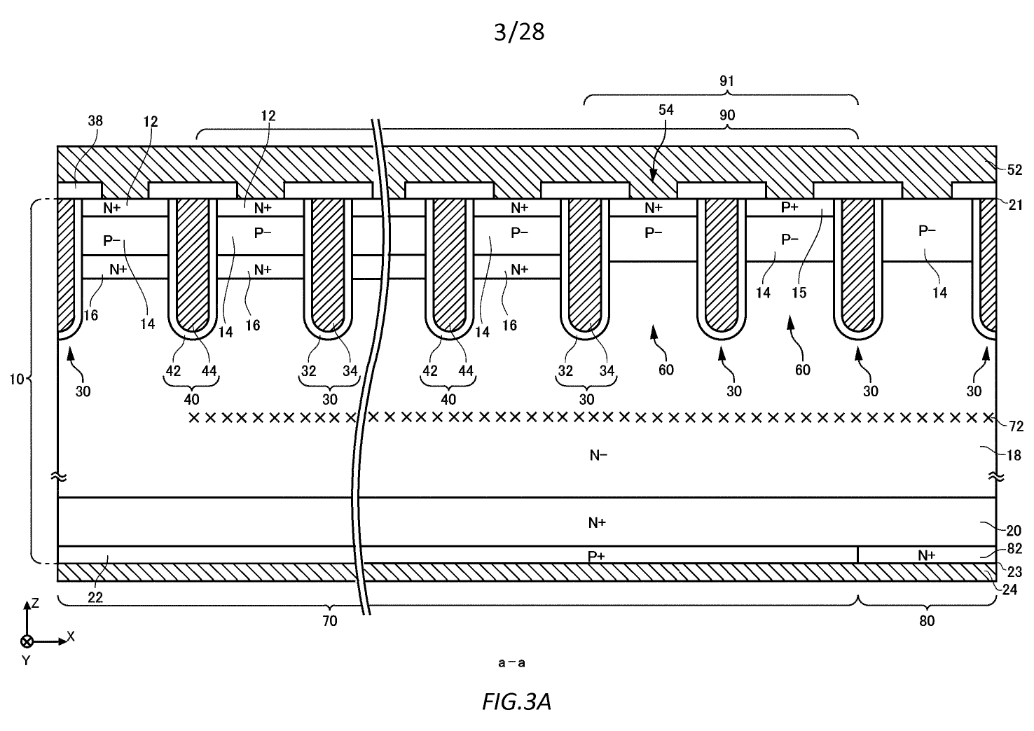

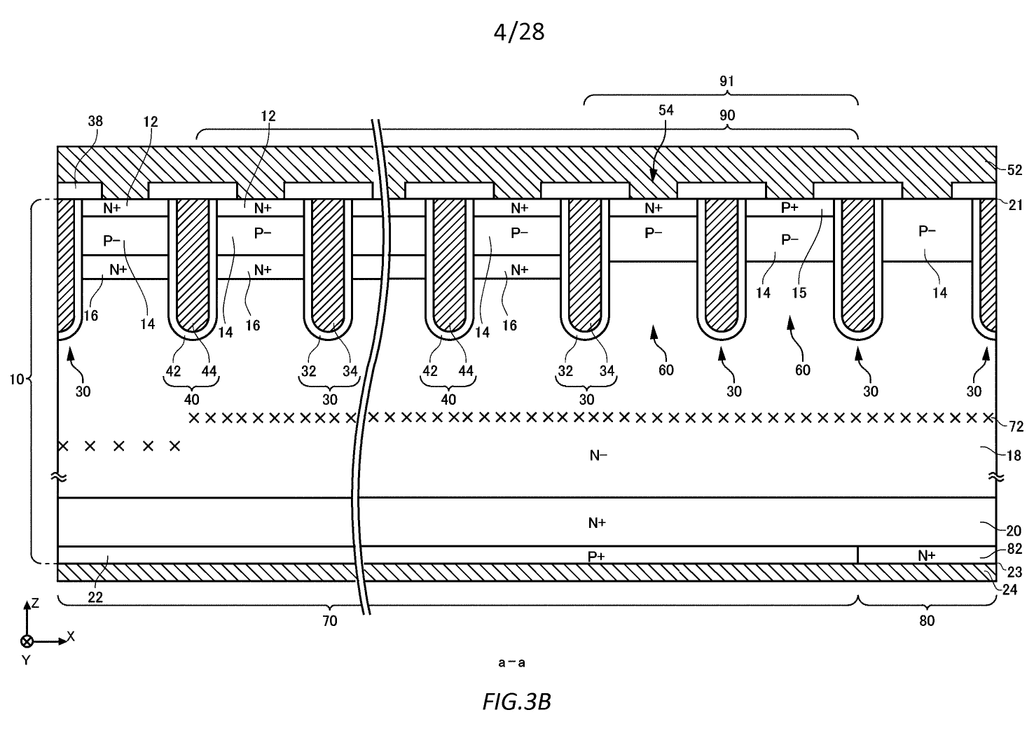

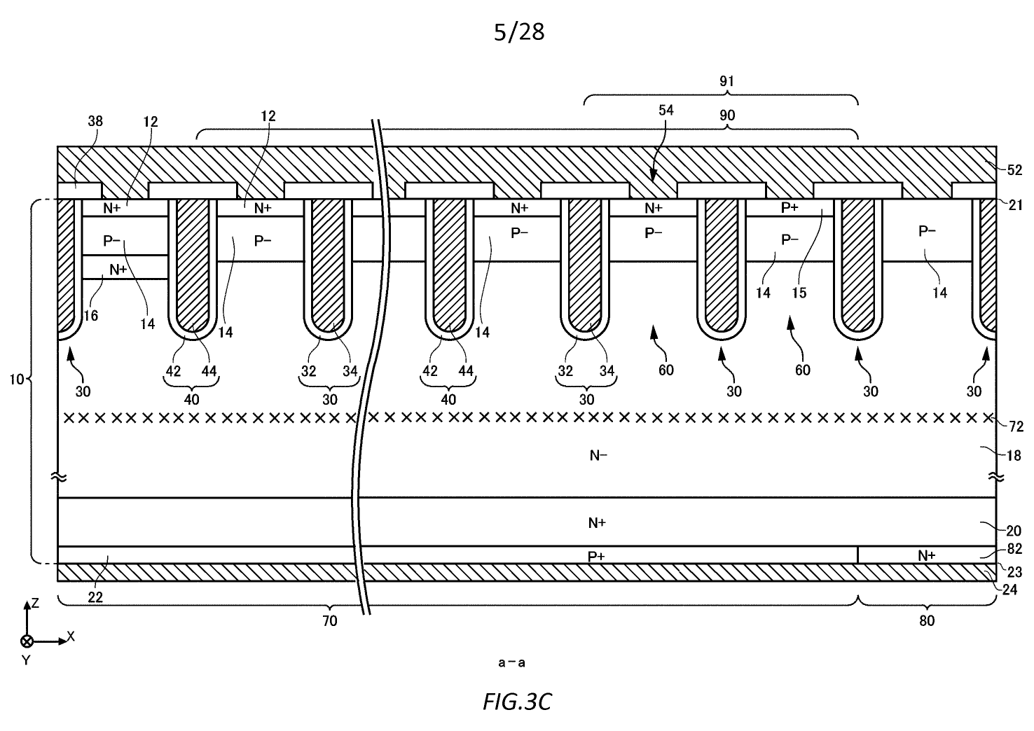

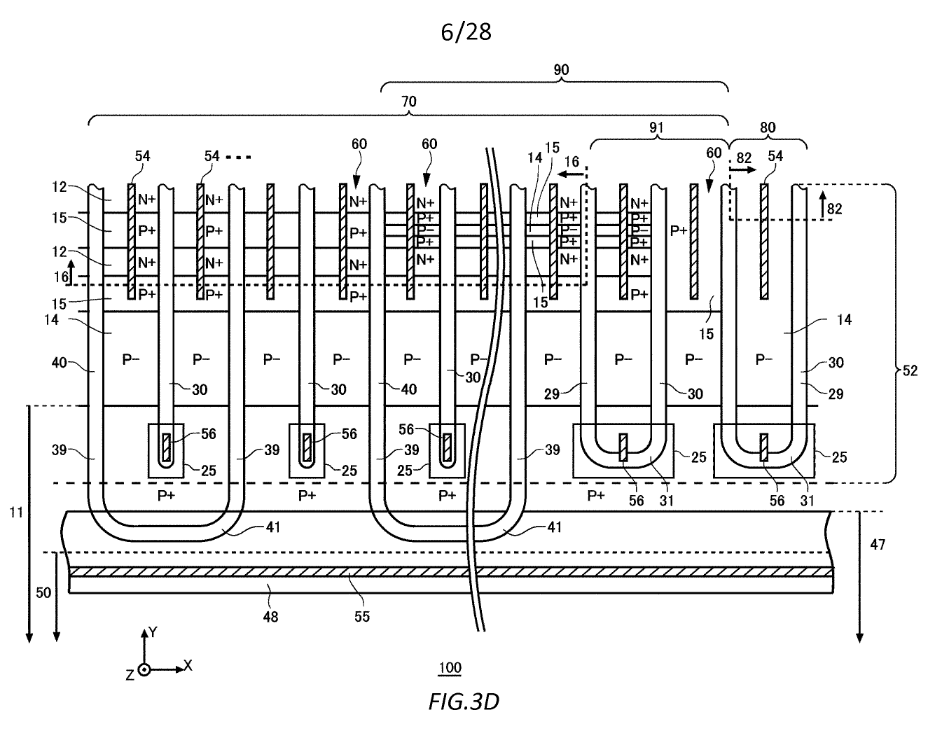

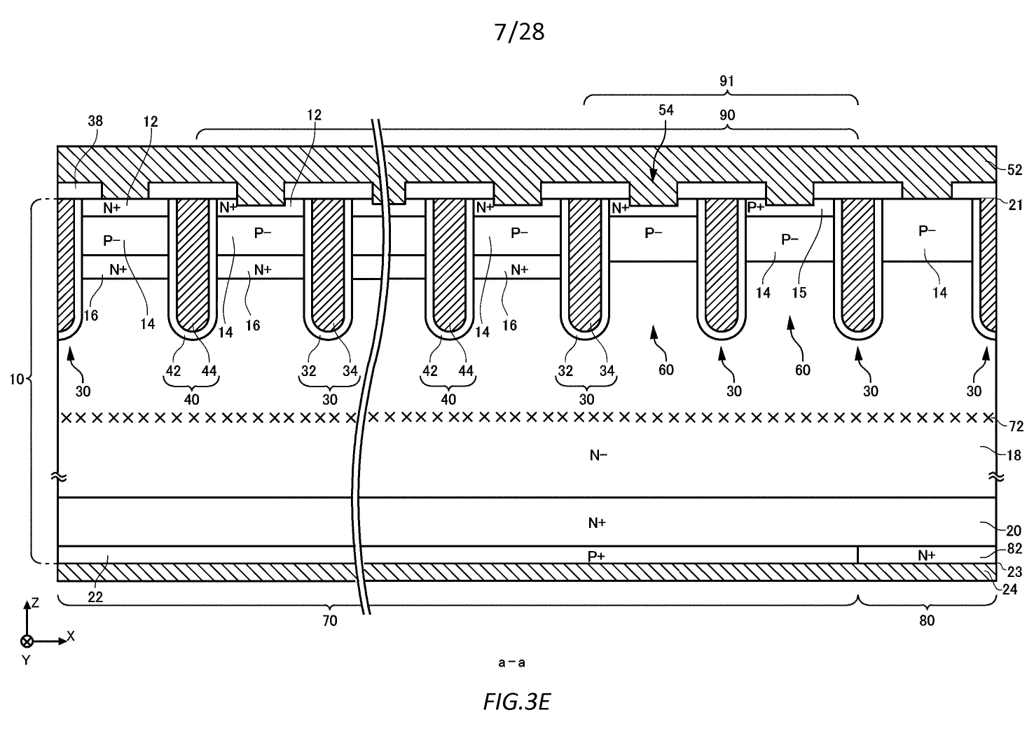

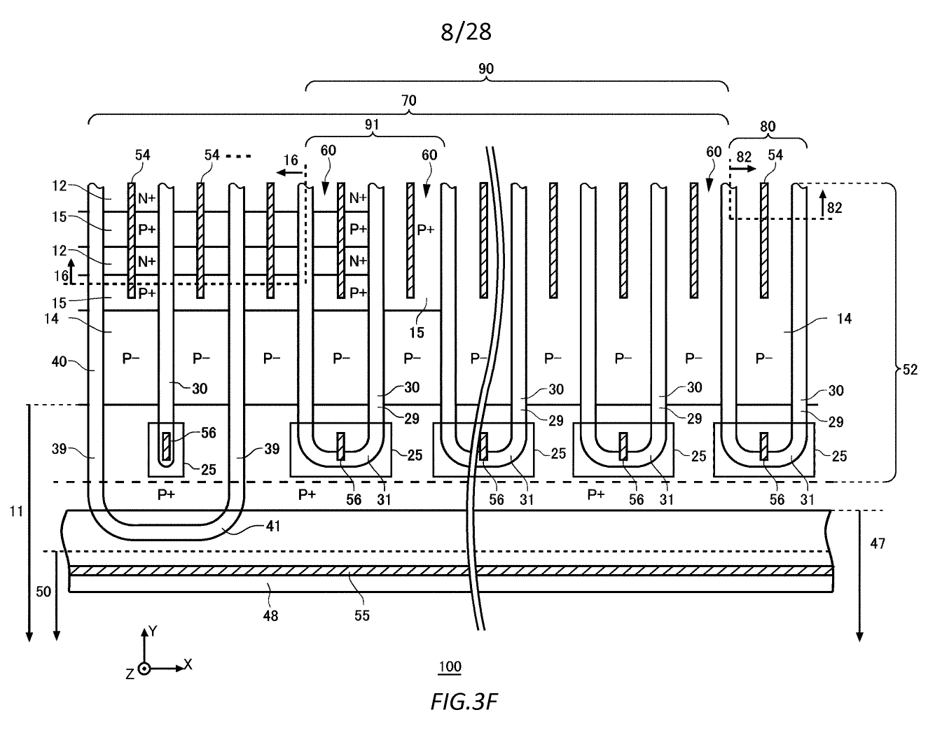

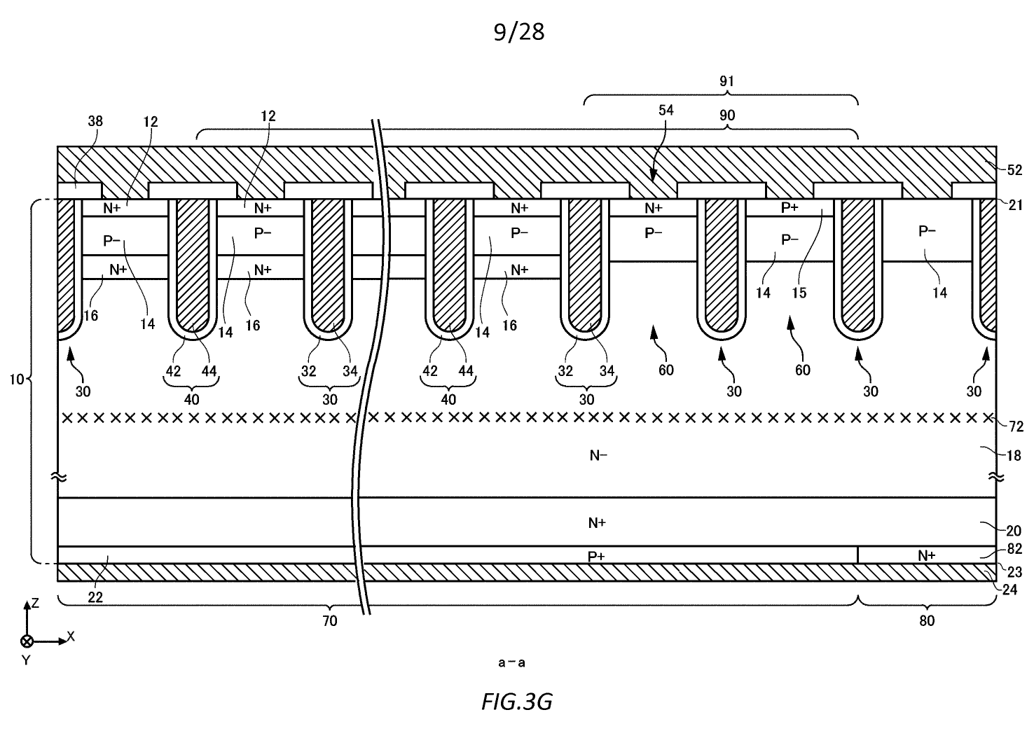

FIG. 3A illustrates an a-a cross section of FIG. 2. The a-a cross section is an XZ plane passing through the contact region 15, the base region 14, the gate trench portion 40, and the dummy trench portion 30. The semiconductor device 100 of the present example includes the semiconductor substrate 10, an interlayer dielectric film 38, the emitter electrode 52, and the collector electrode 24 in the a-a cross section.

The interlayer dielectric film 38 is provided on the front surface 21 of the semiconductor substrate 10. The interlayer dielectric film 38 may be an dielectric film such as the silicate glass to which an impurity such as boron or phosphorus is added. The interlayer dielectric film 38 may be in contact with the front surface 21, or another film such as an oxide film may be provided between the interlayer dielectric film 38 and the front surface 21 of the semiconductor substrate 10. The interlayer dielectric film 38 is provided with the contact hole 54 described in FIG. 2.

The emitter electrode 52 is provided on the front surface 21 of the semiconductor substrate 10 and an upper surface of the interlayer dielectric film 38. The emitter electrode 52 is electrically connected to the front surface 21 of the semiconductor substrate 10 through the contact hole 54 of the interlayer dielectric film 38. A plug (not illustrated) made of tungsten (W) or the like may be embedded inside the contact hole 54 with a barrier metal film interposed therebetween. In addition, a plug region of the P++ type may be provided in a surface layer of the semiconductor substrate 10 in which the contact hole 54 is provided. A doping concentration of the plug region is higher than the doping concentration of the contact region 15.

A collector electrode 24 is provided on a back surface 23 of the semiconductor substrate 10. The emitter electrode 52 and the collector electrode 24 may be formed of a material containing a metal or a laminated film thereof.

The semiconductor substrate 10 may be a single semiconductor substrate such as a silicon substrate or a diamond substrate, or may be a compound semiconductor substrate such as a silicon carbide substrate or a nitride semiconductor such as gallium nitride. The semiconductor substrate 10 of the present example is a silicon substrate.

The semiconductor substrate 10 has a drift region 18 of the first conductivity type. The drift region 18 of the present example is of an N- type. The drift region 18 may be a region remaining in the semiconductor substrate 10 without other doping regions being provided.

Above the drift region 18, one or more accumulation regions 16 may be provided in the Z axis direction. An accumulation region 16 is a region in which a same dopant as that of the drift region 18 is accumulated at a higher concentration than that of the drift region 18. A doping concentration of the accumulation region 16 is higher than a doping concentration of the drift region 18.

The accumulation region 16 of the present example is of the N+ type. The accumulation region 16 may be provided only in the transistor portion 70, or may be provided in both the transistor portion 70 and the diode portion 80. By providing the accumulation region 16, an injection enhancement effect (IE effect) of carriers can be increased to reduce an on-voltage. The accumulation region 16 of the present example is provided only in the transistor portion 70 and is not provided in the diode portion 80.

In the transistor portion 70, the emitter region 12 is provided above the base region 14 in contact with the front surface 21 of the semiconductor substrate 10. The emitter region 12 is provided in contact with the gate trench portion 40. A doping concentration of the emitter region 12 is higher than the doping concentration of the drift region 18. A dopant of the emitter region 12 is, as an example, arsenic (As), phosphorus (P), antimony (Sb), or the like.

In the diode portion 80, the base region 14 exposed on the front surface 21 of the semiconductor substrate 10 is provided. The base region 14 of the diode portion 80 operates as an anode. The base region 14 of the diode portion 80 may be formed at a same concentration and a same depth position as the base region 14 of the transistor portion 70, or may be formed at a different concentration and a different depth position.

Below the drift region 18, a buffer region 20 of the first conductivity type may be provided. The buffer region 20 of the present example is of the N+ type. A doping concentration of the buffer region 20 is higher than the doping concentration of the drift region 18. The buffer region 20 may function as a field stop layer that prevents a depletion layer spreading from a lower surface side of the base region 14 from reaching the collector region 22 and the cathode region 82.

In the transistor portion 70, the collector region 22 is provided below the buffer region 20. The collector region 22 may be provided in contact with the cathode region 82 at the back surface 23 of the semiconductor substrate 10.

In the diode portion 80, the cathode region 82 is provided below the buffer region 20. The cathode region 82 may be provided at a same depth as the collector region 22 of the transistor portion 70, or may be provided to a different depth. The cathode region 82 may partially have a region of the P+ type that is electrically floating or is in contact with the collector electrode 24. The diode portion 80 may function as a freewheeling diode (FWD) that passes a freewheeling current that conducts in a reverse direction when the transistor portion 70 is not conducting.

The semiconductor substrate 10 is provided with the gate trench portion 40 and the dummy trench portion 30. The gate trench portion 40 and the dummy trench portion 30 are provided so as to penetrate through the base region 14 and the accumulation region 16 from the front surface 21 of the semiconductor substrate 10 and reach the drift region 18. The configuration of the trench portion penetrating through the doping region is not limited to the one manufactured in the order of forming the doping region and then forming the trench portion. The configuration of the trench portion penetrating through the doping region includes a configuration of the doping region being formed between the trench portions after forming the trench portion.

The gate trench portion 40 includes a gate trench provided at the front surface 21 of the semiconductor substrate 10, a gate dielectric film 42, and a gate conductive portion 44. The gate dielectric film 42 is provided to cover the inner wall of the gate trench. The gate dielectric film 42 may be formed of an oxide film or a nitride film. The gate conductive portion 44 is provided so as to be embedded on an inner side of the gate dielectric film 42 inside the gate trench. An upper surface of the gate conductive portion 44 may be in a same XY plane as the front surface 21 of the semiconductor substrate 10. The gate dielectric film 42 insulates the gate conductive portion 44 and the semiconductor substrate 10 from each other. The gate conductive portion 44 may be formed of polysilicon or the like doped with an impurity.

The gate conductive portion 44 may be provided longer than the base region 14 in the depth direction. The gate trench portion 40 is covered with the interlayer dielectric film 38 on the front surface 21 of the semiconductor substrate 10. When a predetermined voltage is applied to the gate conductive portion 44, a channel due to an electron inversion layer is formed in a surface layer of an interface of the base region 14 that is in contact with the gate trench.

The dummy trench portion 30 may have a same structure as the gate trench portion 40 in the XZ cross section. The dummy trench portion 30 includes a dummy trench provided at the front surface 21 of the semiconductor substrate 10, a dummy dielectric film 32, and a dummy conductive portion 34. The dummy dielectric film 32 is provided covering an inner wall of the dummy trench. The dummy dielectric film 32 may be formed of an oxide film or a nitride film. The dummy conductive portion 34 is provided so as to be embedded on an inner side of the dummy dielectric film 32 inside the dummy trench. An upper surface of the dummy conductive portion 34 may be in a same XY plane as the front surface 21 of the semiconductor substrate 10. The dummy dielectric film 32 insulates the dummy conductive portion 34 and the semiconductor substrate 10 from each other. The dummy conductive portion 34 may be formed of a same material as that of the gate conductive portion 44.

The gate trench portion 40 and the dummy trench portion 30 of the present example are covered with the interlayer dielectric film 38 on the front surface 21 of the semiconductor substrate 10. It is noted that bottom portions of the dummy trench portion 30 and the gate trench portion 40 may be formed in a curved-surface shape (a curved-line shape in the cross section) convexly downward.

In the diode portion 80, a lifetime control region 72 including a lifetime killer is locally provided in the drift region 18. The lifetime killer is a crystal defect formed at a predetermined depth position in the semiconductor substrate 10 by, for example, implanting helium ions, hydrogen ions (protons, deuterons), or the like. The lifetime control region 72 promotes recombination between holes generated in the base region 14 of the diode portion 80 and electrons injected from the cathode region 82, and suppresses peak current during reverse recovery.

The lifetime control region 72 may be formed by irradiating a proton or helium particle beam from the front surface 21 or the back surface 23 of the semiconductor substrate 10 using a mask. As an example, the proton or helium particle beam is irradiated onto the transistor portion 70 and the diode portion 80 through an opening of a resist mask in a state in which a region in which the lifetime control region 72 is not formed is shielded by the resist mask formed above the front surface 21 of the semiconductor substrate 10. The proton or helium particle beam is not irradiated onto the region shielded by a mask.

In FIG. 3A, a peak position in the Z axis direction of a concentration distribution of the lifetime killer is indicated by a symbol "x". The peak position in the Z axis direction of the lifetime control region 72 of the present example may be equal to a position in the Z axis direction of a lower surface of the well region 11, or may be provided below a position in the Z axis direction of the lower surface of the well region 11. In addition, the lifetime control region 72 may be formed to have a plurality of peaks of the concentration distribution of the lifetime killer in the Z axis direction.

The lifetime control region 72 of the present example is continuously provided, on a front surface 21 side of the semiconductor substrate 10, from the diode portion 80 over at least a part of the transistor portion 70. In the present example, in the transistor portion 70, the lifetime control region 72 is provided in the transition region 90. When the diode portion 80 is conducting, a hole current from not only the base region 14 of the diode portion 80 but also the base region 14 of the transistor portion 70 toward the cathode region 82 is generated. The transistor portion 70 promotes carrier extinction and reduces reverse recovery loss by having the transition region 90 in which the lifetime control region 72 is provided.

However, in the trench portion of the transition region 90 of the present example, when a helium or proton particle beam is irradiated from the front surface 21 or the back surface 23 of the semiconductor substrate 10, the gate dielectric film 42 is damaged and an interface state changes. When a gate voltage is applied to the irradiated gate dielectric film 42, an inversion layer is more easily formed in the adjacent base region 14 than in the gate dielectric film 42 that is not irradiated. Therefore, in the transition region 90 in which the lifetime control region 72 is provided, the threshold voltage decreases as compared with a region of the transistor portion 70 other than the transition region 90. In addition, in the transition region 90 in which the lifetime control region 72 is provided, leakage current increases as compared with the region of the transistor portion 70 other than the transition region 90. Furthermore, in the transition region 90 in which the lifetime control region 72 is provided, conduction loss increases as compared with the region of the transistor portion 70 other than the transition region 90.

In the present example, there is a difference in that the lifetime control region 72 is provided in the transition region 90 and no lifetime control region 72 is provided in the region of the transistor portion 70 other than the transition region 90, but the present disclosure is not limited to this. In another example, as illustrated in FIG. 3B, a difference in characteristics may be provided by changing a form of the lifetime control region 72 between the transition region 90 and the region other than the transition region 90. For example, a concentration of the lifetime killer or a position of the lifetime control region 72 in the Z axis direction may be different.

In addition, as illustrated in FIG. 3C, a difference in characteristics may be provided by changing a configuration of the accumulation region 16 between the transition region 90 and the region other than the transition region 90. For example, regardless of presence or absence of the accumulation region 16, a difference in concentration of the accumulation region 16, a difference in integrated concentration in the Z axis direction, or the like may be provided.

In addition, as illustrated in FIG. 3D, a difference in characteristics may be provided by changing the placement of the contact region 15 between the transition region 90 and the region other than the transition region 90. Alternatively, the area of the contact region 15 may be different between the transition region 90 and the region other than the transition region 90.

In addition, as illustrated in FIG. 3E, a difference in characteristics may be provided by changing a shape of the contact hole 54 between the transition region 90 and the region other than the transition region 90. For example, the depth of the contact hole 54 may be different between the transition region 90 and the region other than the transition region 90, and a width may be different between the transition region 90 and the region other than the transition region 90.

Alternatively, as illustrated in FIG. 3F, the transition region 90 may have an invalid region in which no transistor conduction occurs, without the gate trench portion 40 and the emitter region 12 being provided. The invalid region of the transition region 90 need not have the contact region 15 and the accumulation region 16. The boundary region 91 may be provided between the invalid region of the transition region 90 and the region of the transistor portion 70 other than the transition region 90.

In still another example, as illustrated in FIG. 3G, a difference in configuration need not be provided between the transition region 90 and the region other than the transition region 90. In this case, in the transition region 90, although conduction loss does not increase as compared with the region of the transistor portion 70 other than the transition region 90, the characteristics of the diode portion 80 are affected similarly to the other examples. In any configuration, in the transition region 90, characteristics of the transistor portion 70 and the diode portion 80 are affected.

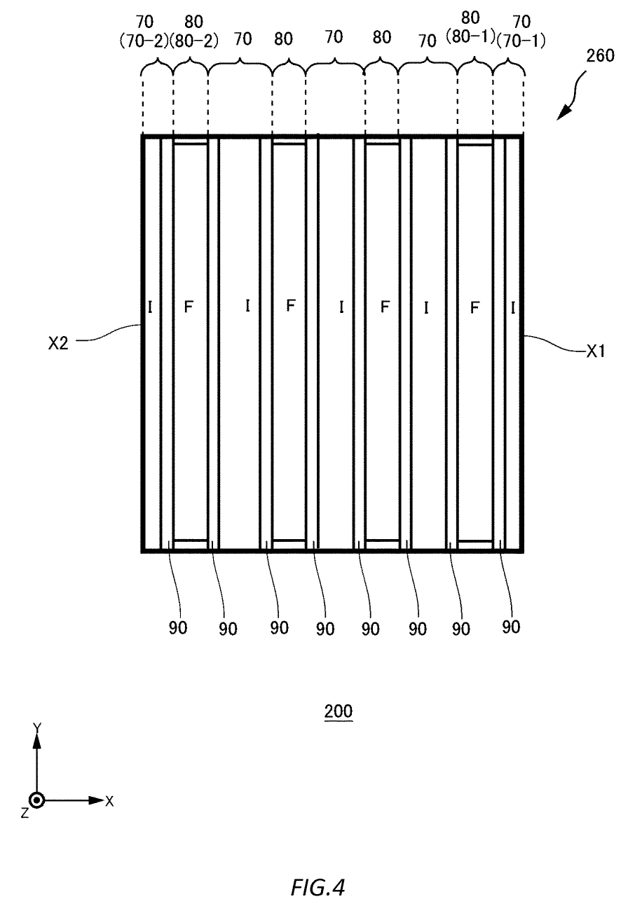

FIG. 4 is a top view illustrating an example of an arrangement of transistor portions 70 and diode portions 80 in a first active portion 260 according to a comparative example. The first active portion 260 has, in the X axis direction, the first end portion X1 and the second end portion X2 on an opposite side to the first end portion X1. Here, the first end portion X1 is defined as the positive side in the X axis direction and the second end portion X2 is defined as the negative side in the X axis direction, but the reverse may also be the case.

The first active portion 260 has a plurality of transistor portions 70 and a plurality of diode portions 80 that are alternately arranged in the X axis direction. On the front surface 21 of the semiconductor substrate 10, an area of the transistor portion 70 may be larger than an area of the diode portion 80. Among the plurality of diode portions 80, the diode portion 80 provided closest to the first end portion X1 is referred to as the first diode portion 80-1, and the diode portion 80 provided closest to the second end portion X2 is referred to as the second diode portion 80-2. Among the plurality of transistor portions 70, the transistor portion 70 provided closest to the first end portion X1 is referred to as the first transistor portion 70-1, and the transistor portion 70 provided closest to the second end portion X2 is referred to as the second transistor portion 70-2.

In the first active portion 260, the first transistor portion 70-1 is provided closer to the first end portion X1 side than the first diode portion 80-1, and the second transistor portion 70-2 is provided closer to the second end portion X2 side than the second diode portion 80-2. In other words, in the first active portion 260, the transistor portions 70 (the first transistor portion 70-1 and the second transistor portion 70-2) are disposed at both ends of the arrangement. On the front surface 21 of the semiconductor substrate 10, an area of each of the first transistor portion 70-1 and the second transistor portion 70-2 may be the same as an area of another transistor portion 70, or may be smaller than the area of another transistor portion 70.

In the example of FIG. 4, the first active portion 260 has five transistor portions 70 and four diode portions 80. Each transistor portion 70 has the transition region 90 on an adjacent diode portion 80 side. The transition region 90 is a region in the transistor portion 70 that is in contact with the diode portion 80. The four diode portions 80 illustrated in FIG. 4 are adjacent to the transistor portions 70 at both ends in the X axis direction, and thus eight transition regions 90, in proportion to the number of diode portions 80, are provided.

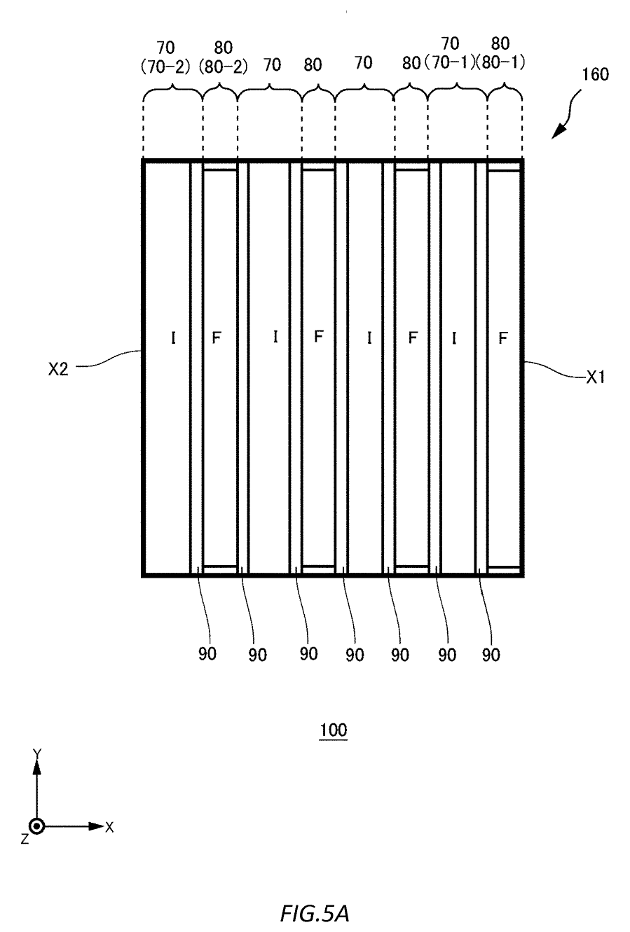

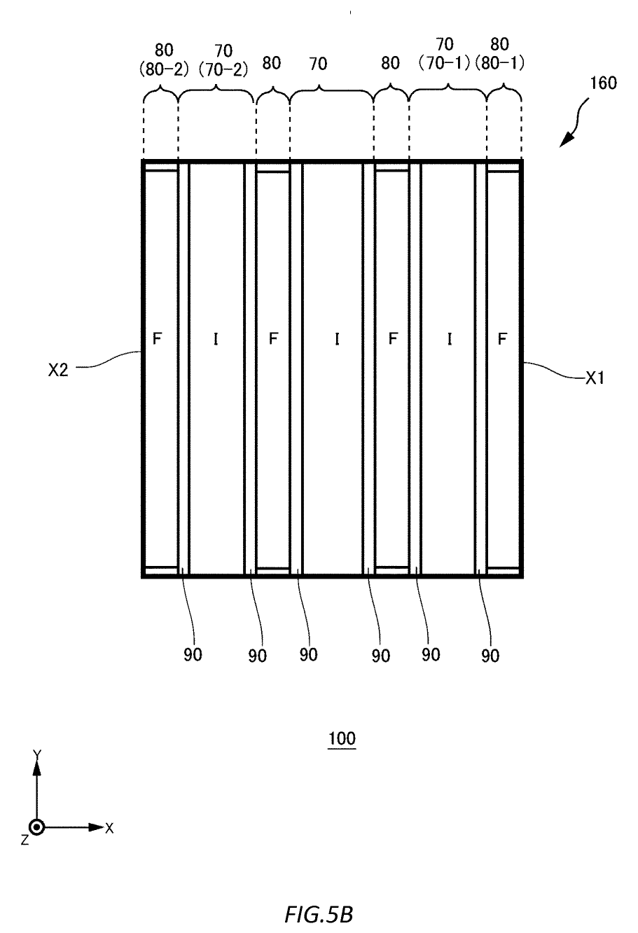

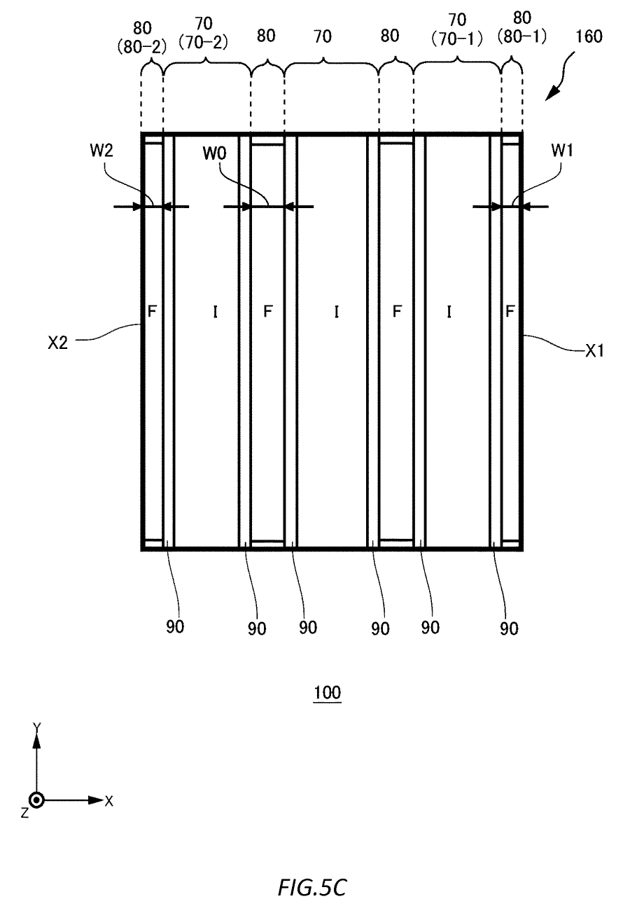

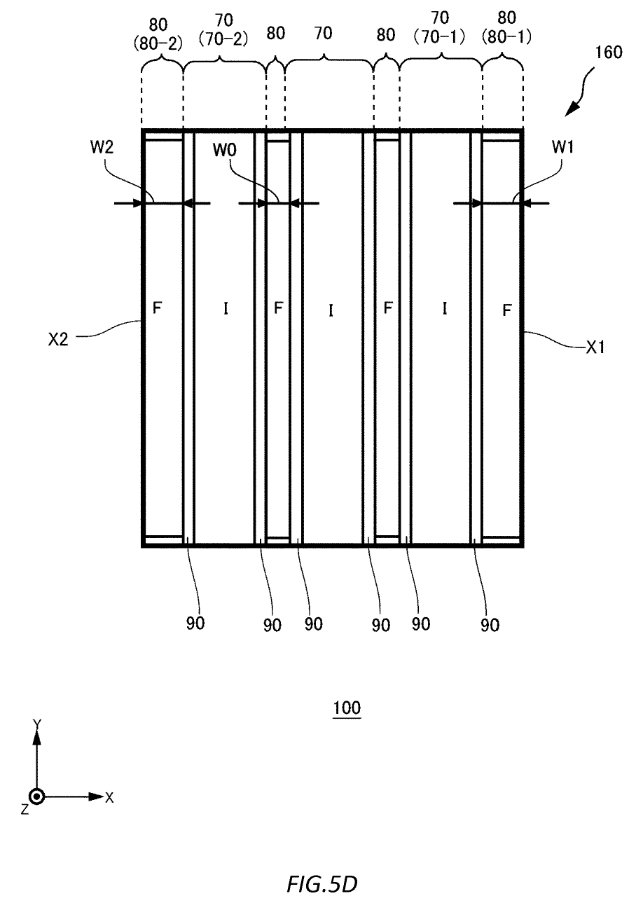

FIG. 5A is a top view illustrating an example of an arrangement of transistor portions 70 and diode portions 80 in the first active portion 160. Similarly to the first active portion 260, the first active portion 160 has, in the X axis direction, the first end portion X1 and the second end portion X2 on an opposite side to the first end portion X1. In FIG. 5A, the first end portion X1 is on the positive side in the X axis direction and the second end portion X2 is on the negative side in the X axis direction, but the reverse may also be the case.

Similarly to the first active portion 260, the first active portion 160 has a plurality of transistor portions 70 and a plurality of diode portions 80 alternately arranged in the X axis direction. Among the plurality of diode portions 80, the diode portion 80 provided closest to the first end portion X1 is referred to as the first diode portion 80-1, and the diode portion 80 provided closest to the second end portion X2 is referred to as the second diode portion 80-2. Among the plurality of transistor portions 70, the transistor portion 70 provided closest to the first end portion X1 is referred to as the first transistor portion 70-1, and the transistor portion 70 provided closest to the second end portion X2 is referred to as the second transistor portion 70-2.

The first diode portion 80-1 of the present example is provided closer to the first end portion X1 side than the first transistor portion 70-1. In other words, in the arrangement of the transistor portions 70 and the diode portions 80, the first diode portion 80-1 is provided closest to the first end portion X1 side. The first diode portion 80-1 may be provided at the first end portion X1, or may be provided spaced apart from the first end portion X1.

The second transistor portion 70-2 of the present example is provided closer to the second end portion X2 side than the second diode portion 80-2. In other words, in the arrangement of the transistor portions 70 and the diode portions 80, the second transistor portion 70-2 is provided closest to the second end portion X2 side. The second transistor portion 70-2 may be provided at the second end portion X2, or may be provided spaced apart from the second end portion X2.

On the front surface 21 of the semiconductor substrate 10, a ratio of the area of the transistor portion 70 to the area of the diode portion 80 in the first active portion 160 of FIG. 5A may be the same as that in the first active portion 260 of FIG. 4.

Similarly to the first active portion 260, each transistor portion 70 has the transition region 90 on an adjacent diode portion 80 side. The first active portion 160 of FIG. 5A has four transistor portions 70 and four diode portions 80, and has seven transition regions 90.

The transition region 90 of the present example is a region of the transistor portion 70 in which the lifetime control region 72 is provided to reduce reverse recovery loss of the diode portion 80. When a ratio of an area of the transition region 90 to the area of the transistor portion 70 becomes high, performance of the transistor portion 70 decreases. In addition, the influence on the diode portion 80 increases.

In the first active portion 160 of the present example and the first active portion 260 according to the comparative example, the number of diode portions 80 is the same. However, in the first active portion 160, no transistor portion 70 is provided on the first end portion X1 side of the first diode portion 80-1, and therefore no transition region 90 is provided there either. Therefore, the number of transition regions 90 in the first active portion 160 is smaller than the number of transition regions 90 in the first active portion 260.

Thus, in the first active portion 160 of the present example, on the front surface 21 of the semiconductor substrate 10, it is possible to reduce a ratio of the area of the transition region 90 to the area of the transistor portion 70 as compared with the first active portion 260, to improve characteristics in the transistor portion 70, and to decrease the influence on the diode portion 80. Thus, in the first active portion 160 of the present example, characteristics are improved more than in the first active portion 260, and therefore the ratio of the area of the transistor portion 70 to the area of the diode portion 80 may be the same as or different from that in the first active portion 260.

FIG. 5B is a top view illustrating another example of the arrangement of the transistor portions 70 and the diode portions 80 in the first active portion 160. Here, components common to those of the first active portion 160 of FIG. 5A are denoted by same reference signs and description thereof is omitted, and description will focus on differences from FIG. 5A.

In the present example, the second diode portion 80-2 is provided closer to the second end portion X2 side than the second transistor portion 70-2. In other words, in the first active portion 160 of the present example, the diode portions 80 (the first diode portion 80-1 and the second diode portion 80-2) are disposed at both ends of the arrangement. The first active portion 160 of FIG. 5B includes three transistor portions 70 and four diode portions 80, and includes six transition regions 90. Unlike the first active portion 160 of FIG. 5A, no transistor portion 70 is provided on a second end portion X2 side of the second diode portion 80-2, and therefore no transition region 90 is provided there either. Therefore, the number of transition regions 90 in the first active portion 160 of FIG. 5B is even smaller than the number of transition regions 90 in the first active portion 160 of FIG. 5A. In addition, since the number of transistor portions 70 is also smaller than that in the first active portion 160 of FIG. 5A, the area of each transistor portion 70 on the front surface 21 of the semiconductor substrate 10 is larger.

Thus, in the first active portion 160 of the present example, on the front surface 21 of the semiconductor substrate 10, it is possible to further reduce the ratio of the area of the transition region 90 to the area of the transistor portion 70 as compared with the first active portion 260, to further improve characteristics in the transistor portion 70, and to decrease the influence on the diode portion 80. Thus, in the first active portion 160 of the present example, characteristics are improved more than in the first active portion 260, and therefore the ratio of the area of the transistor portion 70 to the area of the diode portion 80 may be the same as or different from that in the first active portion 260.

FIG. 5C is a modification example of the arrangement of the transistor portions 70 and the diode portions 80 illustrated in FIG. 5B. The numbers of transistor portions 70 and diode portions 80 included in the first active portion 160 of FIG. 5C are the same as those in FIG. 5B. However, in the present example, on the front surface 21 of the semiconductor substrate 10, areas of the first diode portion 80-1 and the second diode portion 80-2 are different from areas of the other diode portions 80.

As illustrated in FIG. 5C, areas of the second diode portion 80-1 and the second diode portion 80-2 may be smaller than areas of the other diode portions 80. In other words, in the X axis direction, the width W1 of the first diode portion 80-1 and the width W2 of the second diode portion 80-2 may be smaller than the width W of the other diode portions 80. The width W1 of the first diode portion 80-1 and the width W2 of the second diode portion 80-2 may be the same as or different from each other. In the first active portion 160 of FIG. 5C, a total area of the diode portions 80 is smaller than that in the first active portion 160 of FIG. 5B, and therefore the area of each transistor portion 70 on the front surface 21 of the semiconductor substrate 10 is larger. Depending on required characteristics, also in the first active portion 160 of FIG. 5C, an area of one diode portion 80 may be changed so that an area ratio between the transistor portion 70 and the diode portion 80 may be the same as that in the first active portion of FIG. 5B, or the total area of the diode portions 80 may be larger than that in the first active portion of FIG. 5B.

FIG. 5D is a modification example of the arrangement of the transistor portions 70 and the diode portions 80 illustrated in FIG. 5B. The numbers of transistor portions 70 and diode portions 80 included in the first active portion 160 of FIG. 5D are the same as those in FIG. 5B. As illustrated in FIG. 5D, on the front surface 21 of the semiconductor substrate 10, the areas of the second diode portion 80-1 and the second diode portion 80-2 may be larger than areas of the other diode portions 80. In other words, in the X axis direction, the width W1 of the first diode portion 80-1 and the width W2 of the second diode portion 80-2 may be larger than the width W of the other diode portions 80. The width W1 of the first diode portion 80-1 and the width W2 of the second diode portion 80-2 may be the same as or different from each other. In the first active portion 160 of FIG. 5D, the total area of the diode portions 80 on the front surface 21 of the semiconductor substrate 10 is larger than that in the first active portion 160 of FIG. 5B, and therefore the area of each transistor portion 70 is smaller. Depending on required characteristics, also in the first active portion 160 of FIG. 5D, the area of one diode portion 80 may be changed so that the area ratio between the transistor portion 70 and the diode portion 80 may be the same as that in the first active portion of FIG. 5B, or the total area of the diode portions 80 may be smaller than that in the first active portion of FIG. 5B.

Thus, as in the first active portions 160 of FIG. 5C and FIG. 5D, on the front surface 21 of the semiconductor substrate 10, it is possible to set the area ratio between the transistor portion 70 and the diode portion 80 in accordance with the required area ratio of the transition region 90.

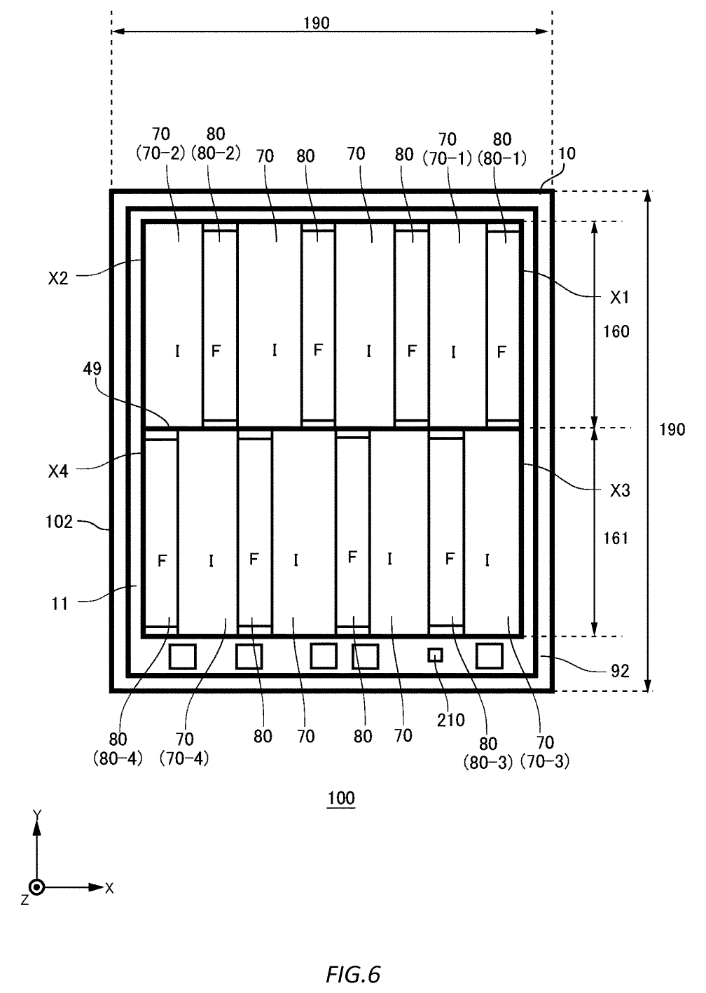

FIG. 6 illustrates another example of an upper surface of the semiconductor device 100. The semiconductor device 100 of the present example has a plurality of active portions obtained by division in the Y axis direction, and is an example in which an arrangement of the transistor portions 70 and the diode portions 80 is different in each active portion. In the present example, in a top view, a region surrounded by the well region 11 in a region on a positive side in the Y axis direction relative to a boundary 49 is defined as the first active portion 160, and a region surrounded by the well region 11 in a region on a negative side in the Y axis direction relative to the boundary 49 is defined as a second active portion 161. The boundary 49 may entirely extend in alignment with the X axis direction, or may entirely or partially form the angle of 0° or more with the X axis direction. The boundary 49 of the present example extends in the X axis direction. The first active portion 160 has, in the X axis direction, the first end portion X1 and the second end portion X2 on an opposite side to the first end portion X1. The second active portion 161 is separated from the first active portion 160 at the boundary 49, and similarly to the first active portion 160, has a plurality of transistor portions 70 and a plurality of diode portions 80 alternately arranged in the X axis direction. The second active portion 161 has, in the X axis direction, a third end portion X3 and a fourth end portion X4 on an opposite side to the third end portion X3. In the Y axis direction, the third end portion X3 is adjacent to the first end portion X1 of the first active portion 160, and the fourth end portion X4 is adjacent to the second end portion X2 of the first active portion 160.

The boundary 49 may further include an inner gate runner that extends in the X axis direction near a center of the semiconductor substrate 10 at the front surface 21 of the semiconductor substrate 10 and is connected to the outer peripheral gate runner 47. The inner gate runner is an example of a gate runner that electrically connects conductive portions of the gate trench portions of the first active portion 160 and the second active portion 161 to a gate pad, similarly to the outer peripheral gate runner 47. The inner gate runner may be formed with a structure similar to that of the outer peripheral gate runner 47, and may include the well region 11, the gate metal layer 50, the semiconductor gate runner 48, and the like.

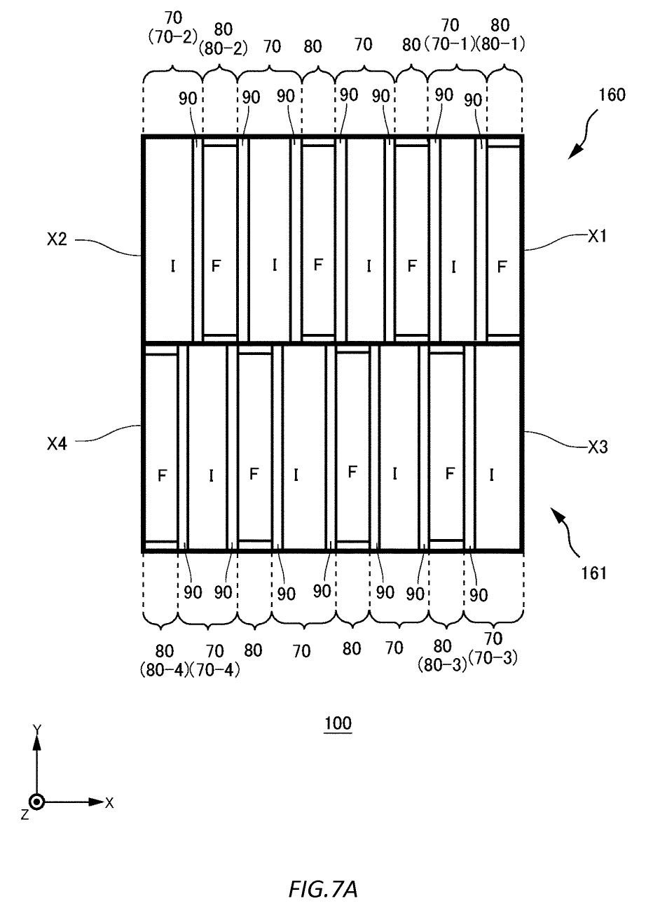

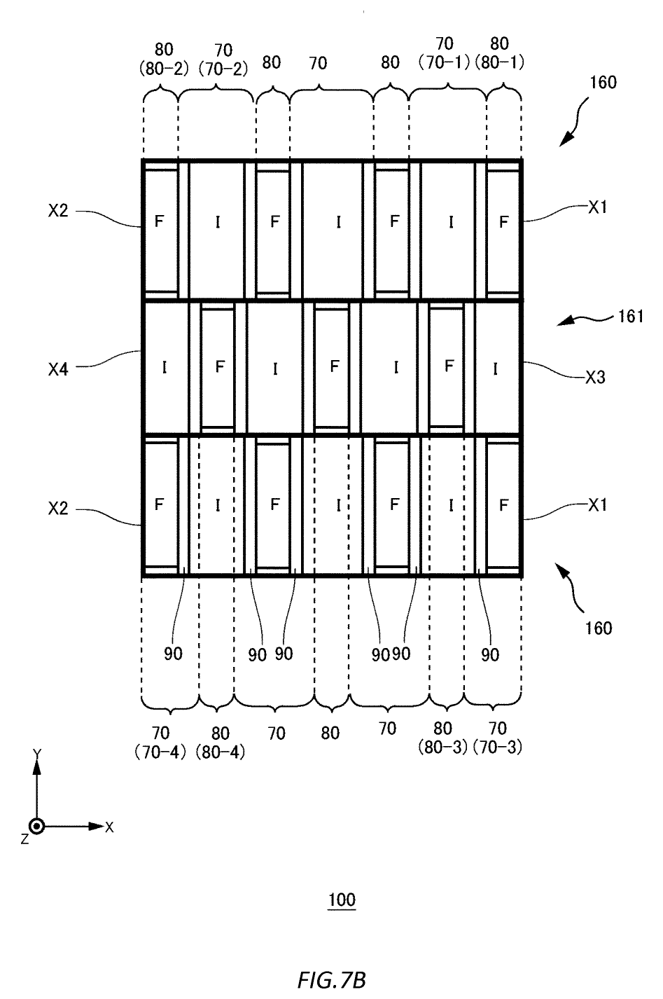

FIG. 7A is a top view illustrating an example of an arrangement of transistor portions 70 and diode portions 80 in the first active portion 160 and the second active portion 161.

Among the plurality of diode portions 80 in the second active portion 161, the diode portion 80 provided closest to the third end portion X3 is referred to as a third diode portion 80-3, and the diode portion 80 provided closest to the fourth end portion X4 is referred to as a fourth diode portion 80-4. Among the plurality of transistor portions 70 in the second active portion 161, the transistor portion 70 provided closest to the third end portion X3 is referred to as a third transistor portion 70-3, and the transistor portion 70 provided closest to the fourth end portion X4 is referred to as a fourth transistor portion 70-4.

The arrangement of the plurality of transistor portions 70 and the plurality of diode portions 80 in the second active portion 161 is different from the arrangement of the plurality of transistor portions 70 and the plurality of diode portions 80 in the first active portion 160.

In the first active portion 160 of the present example, the first diode portion 80-1 is provided closer to the first end portion X1 side than the first transistor portion 70-1, and in the second active portion 161, the third transistor portion 70-3 is provided closer to the third end portion X3 side than the third diode portion 80-3. In other words, in the Y axis direction, the first diode portion 80-1 of the first active portion 160 and the third transistor portion 70-3 of the second active portion 161 are adjacent to each other.

In the first active portion 160 of the present example, the second transistor portion 70-2 is provided closer to the second end portion X2 side than the second diode portion 80-2, and in the second active portion 161, the fourth diode portion 80-4 is provided closer to the fourth end portion X4 side than the fourth transistor portion 70-4. In other words, in the Y axis direction, the second transistor portion 70-2 of the first active portion 160 and the fourth diode portion 80-4 of the second active portion 161 are adjacent to each other.

The first active portion 160 and the second active portion 161 in FIG. 7A each have four transistor portions 70 and four diode portions 80, and have seven transition regions 90. In other words, the number of transition regions 90 in the first active portion 160 is equal to the number of transition regions 90 in the second active portion 161. Thus, the transistor portions 70 and the diode portions 80 of the first active portion 160 and the second active portion 161 are arranged symmetrically in the X axis direction.

On the front surface 21 of the semiconductor substrate 10, the area of each transistor portion 70 may be larger than the area of each diode portion 80. In the Y axis direction, the diode portion 80 of the first active portion 160 may be adjacent to the transistor portion 70 of the second active portion 161, and the diode portion 80 of the second active portion 161 may be adjacent to the transistor portion 70 of the first active portion 160.

FIG. 7B is a top view illustrating another example of the arrangement of the transistor portions 70 and the diode portions 80 in the first active portion 160 and the second active portion 161. In the present example, a plurality of first active portions 160 are provided. The semiconductor device 100 in FIG. 7B has two first active portions 160 and one second active portion 161, and the second active portion 161 is adjacent to the first active portion 160 on the positive side and the negative side in the Y axis direction.

In the first active portion 160 of the present example, the first diode portion 80-1 is provided closer to the first end portion X1 side than the first transistor portion 70-1, and the second diode portion 80-2 is provided closer to the second end portion X2 side than the second transistor portion 70-2. On the other hand, in the second active portion 161, the third transistor portion 70-3 is provided closer to the third end portion X3 side than the third diode portion 80-3, and the fourth transistor portion 70-4 is provided closer to the fourth end portion X4 side than the fourth diode portion 80-4.

The first active portion 160 in FIG. 6 has three transistor portions 70 and four diode portions 80, and has seven transition regions 90. The second active portion 161 has four transistor portions 70 and three diode portions 80, and has seven transition regions 90. In other words, the number of transition regions 90 in the first active portion 160 is equal to the number of transition regions 90 in the second active portion 161. Thus, the diode portions 80 of the first active portion 160 and the second active portion 161 are arranged in the lattice pattern.

On the front surface 21 of the semiconductor substrate 10, the area of each transistor portion 70 may be larger than the area of each diode portion 80. In the Y axis direction, the diode portion 80 of the first active portion 160 may be adjacent to the transistor portion 70 of the second active portion 161, and the diode portion 80 of the second active portion 161 may be adjacent to the transistor portion 70 of the first active portion 160.

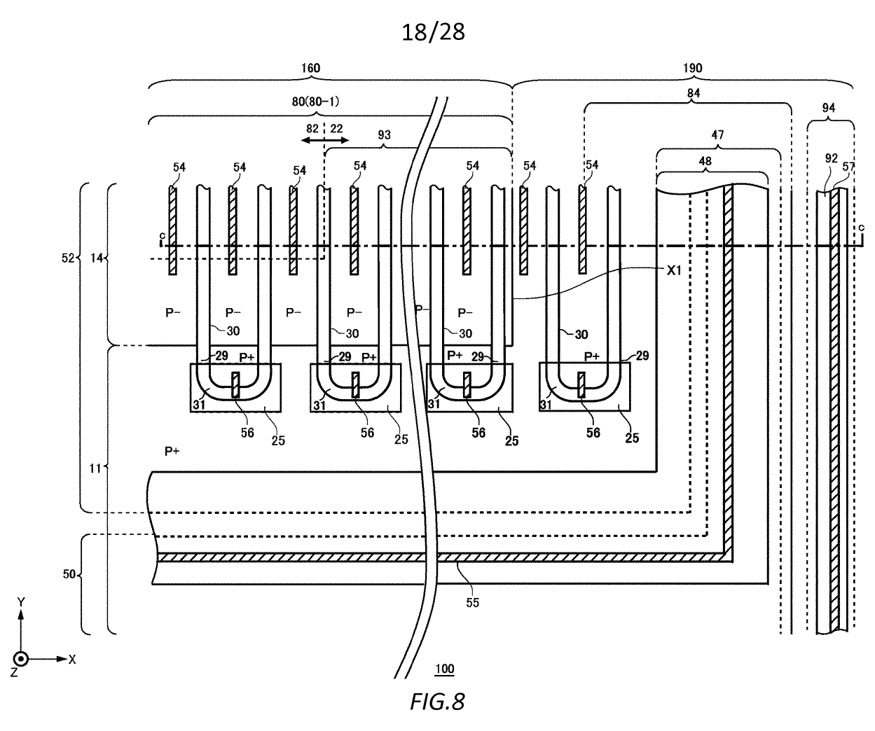

FIG. 8 is a top view in which an example of a region B in FIG. 1 is enlarged. The region B is an XY plane including a vicinity of an end portion of the first diode portion 80-1 of the first active portion 160 on the negative side in the Y axis direction and a vicinity of an end portion thereof on the positive side in the X axis direction. The first active portion 160 of the present example is surrounded by the well region 11 in a top view. In the present example, the region surrounded by the well region 11 in a top view is the first active portion 160, and the region extending from the well region 11 toward the end side 102 side is the outer peripheral region 190. The well region 11 extends overlapping with the outer peripheral gate runner 47, and is annularly provided in a top view. On an outer side of the well region 11, a field plate 94 and the guard ring 92 that form the edge termination region are provided. The field plate 94 and the guard ring 92 are connected through a contact hole 57. The field plate 94 is insulated from the emitter electrode 52 and the outer peripheral gate runner 47.

The first diode portion 80-1 of the present example is provided, in the X axis direction, on an inner side of an end portion (the first end portion X1) of the first active portion 160. In a region adjacent to the first end portion X1 of the first diode portion 80-1, an outer edge portion 93 is provided. The outer edge portion 93 of the present example has the base region 14 provided on the front surface 21 of the semiconductor substrate 10. In other words, the outer edge portion 93 has a front surface structure similar to that of the diode portion 80.

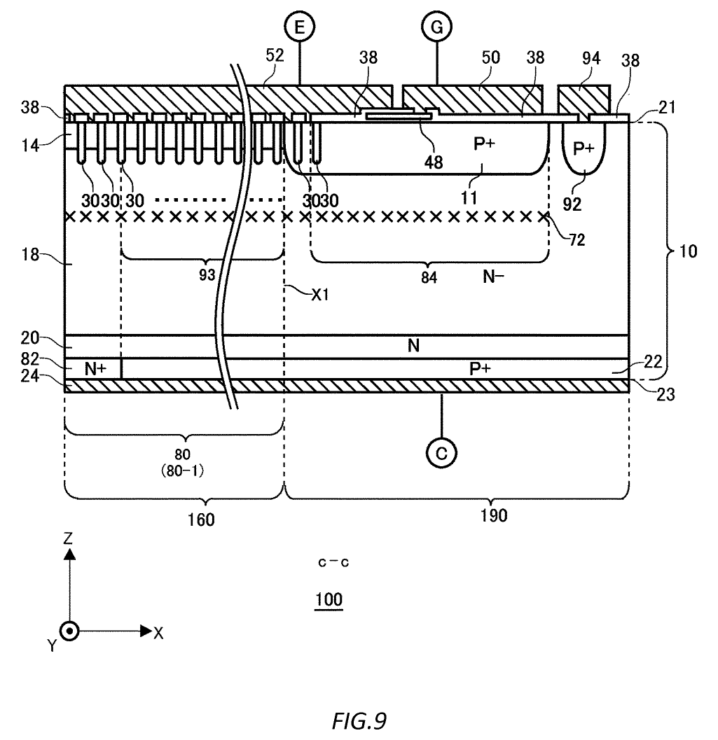

FIG. 9 illustrates a c-c cross section of FIG. 8. The outer edge portion 93 of the present example differs in structure from other diode portions 80 in that the collector region 22 is provided at the back surface 23 of the semiconductor substrate 10.

When the first diode portion 80-1 is provided at the first end portion X1 of the first active portion 160, the distance between the cathode region 82 of the first diode portion 80-1 and the well region 11 is short. Therefore, operation of the well region 11 as the diode may increase a reverse recovery current, resulting in an increase in reverse recovery loss. Therefore, in the present example, since the outer edge portion 93 is provided on the first end portion X1 side of the first diode portion 80-1, in the X axis direction, an outer end portion of the cathode region 82 of the first diode portion 80-1 is located on an inner side of an inner end portion of the well region 11. Thus, it is possible to suppress diode operation of the well region 11 and suppress an increase in reverse recovery loss.

In another example, the outer edge portion 93 may not be provided, and a boundary between the cathode region 82 and the collector region 22 may coincide with a boundary between the base region 14 and the well region 11, and the cathode region 82 may be provided to below the well region 11. In still another example, at the back surface 23 of the outer edge portion 93 and the outer peripheral region 190, an N type semiconductor region having a lower concentration than the cathode region 82 or a P type semiconductor region having a lower concentration than the collector region 22 may be provided in place of the collector region 22.

In addition, the well region 11 has a resistor portion 84 provided from the contact hole 54 provided closest to the end side 102 side to an end portion on the end side 102 side. The resistor portion 84 may have or may not have at least one trench portion (dummy trench portion 30).

A width of the resistor portion 84 in the X axis direction may be 20 μm to 200 μm, more preferably 30 μm to 120 μm, or may be 4% to 100%, more preferably 6% to 60%, of the width of the first diode portion 80-1.

Thus, by providing the resistor portion 84 in which no contact hole 54 is provided in the well region 11, it is possible to suppress concentration of the current from the cathode region 82 on the end side 102 side of the well region 11.

The lifetime control region 72 of the present example is provided extending from the first diode portion 80-1 to at least a part of the well region 11 in the X axis direction. The lifetime control region 72 may be provided below the well region 11.

Thus, in the present example, by providing the lifetime control region 72 below the base region 14 of the first diode portion 80-1 and the well region 11, it is possible to reduce a reverse recovery current and reduce reverse recovery loss.

In another example, the lifetime control region 72 need not be provided to below the well region 11. In still another example, the lifetime control region 72 need not be provided in the outer edge portion 93. In another different example, the lifetime control region 72 may be provided to below the guard ring 92.

Note that FIGS. 8 and 9 may be applied not only to the first active portions 160 of FIGS. 5A to 5D but also to the first active portions 160 of FIGS. 6 to 7B.

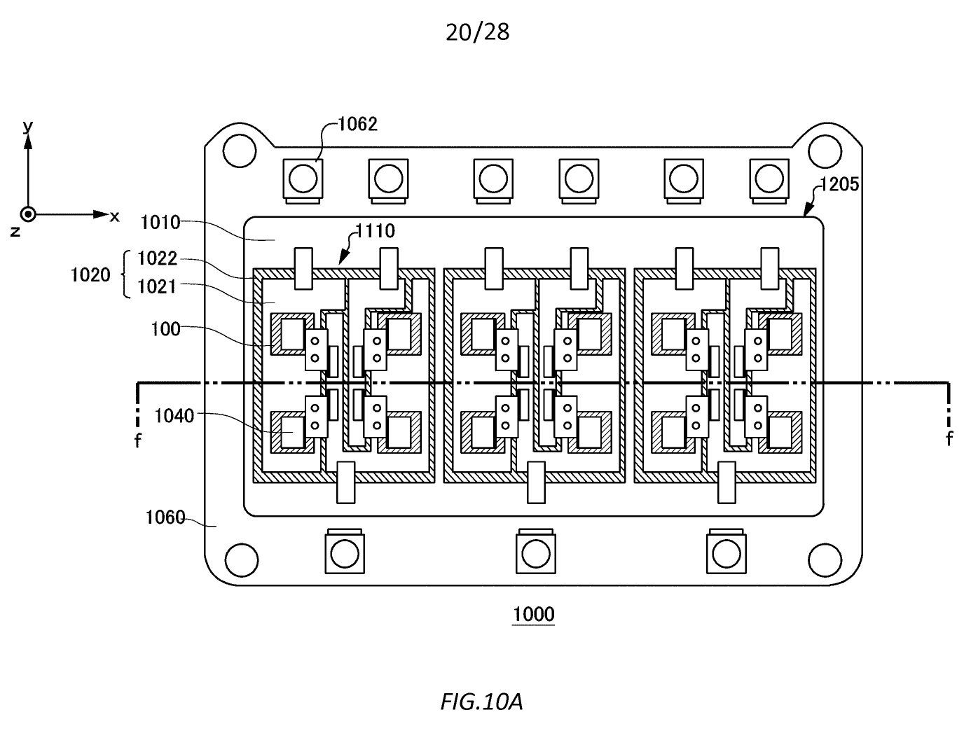

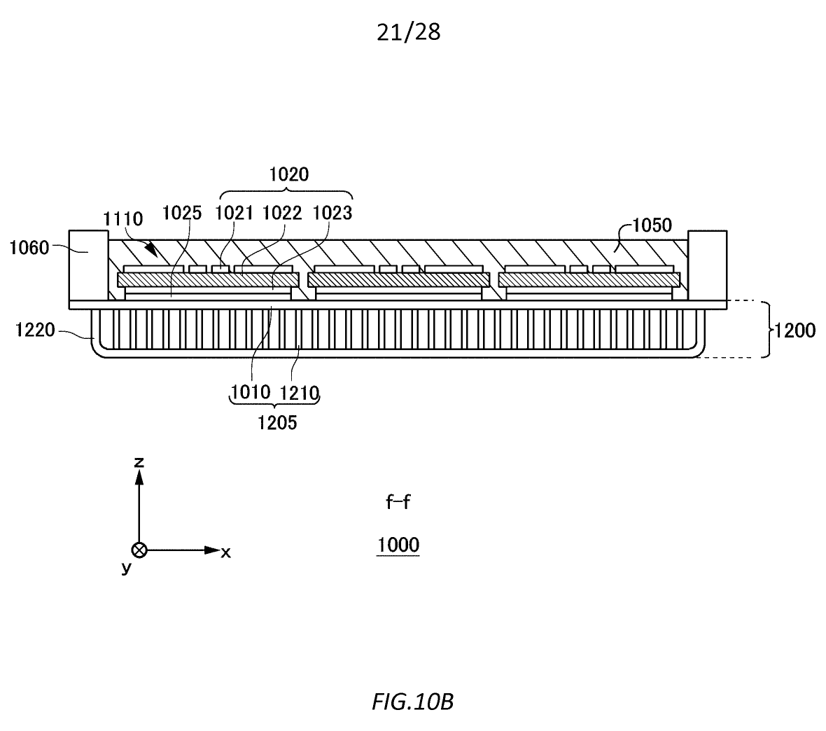

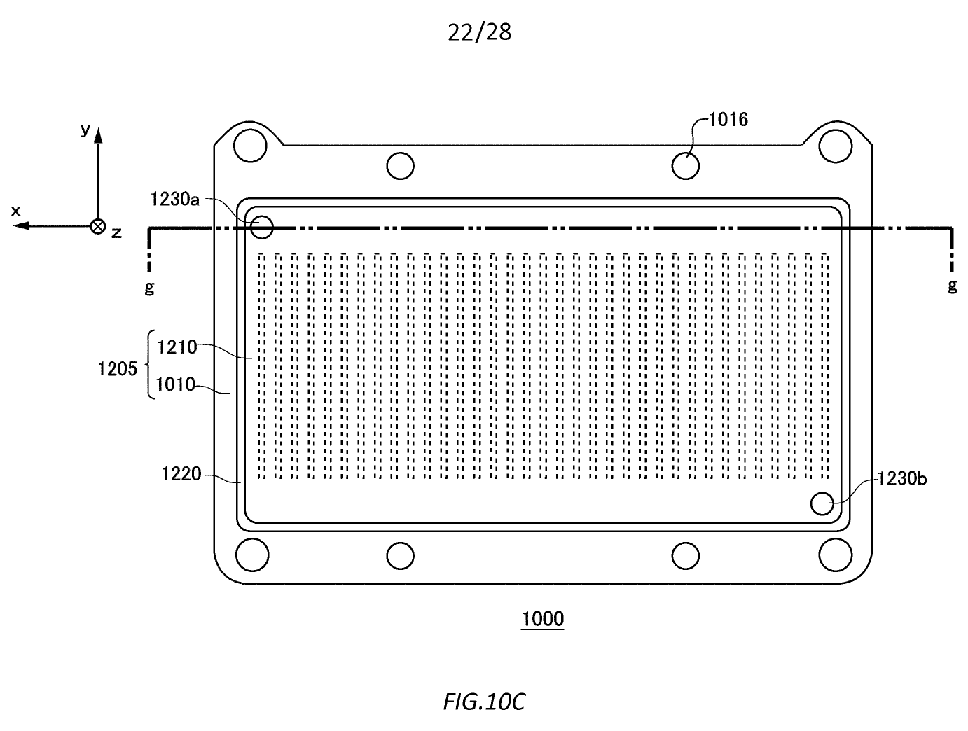

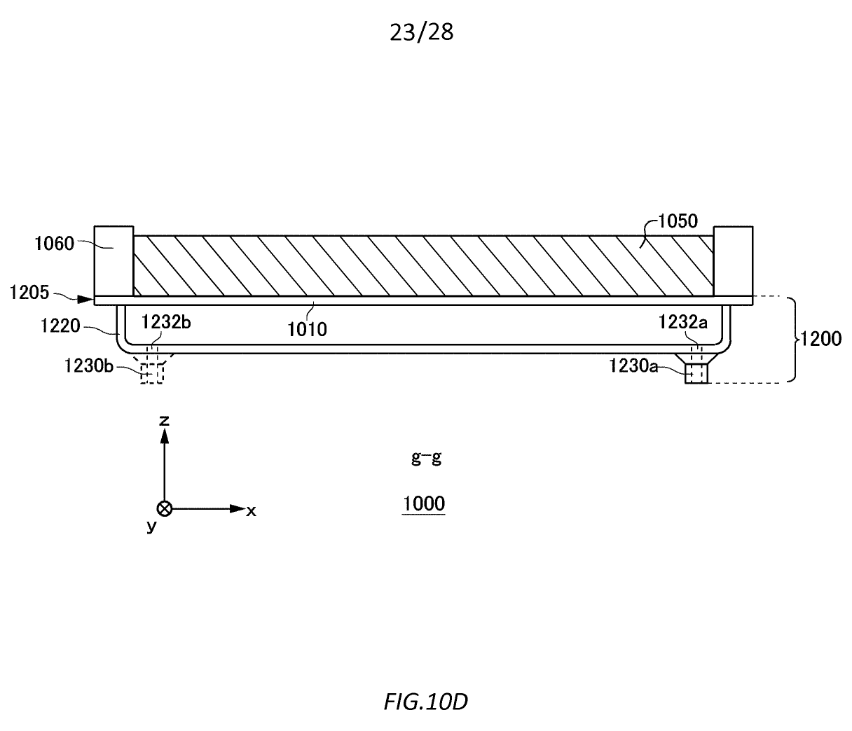

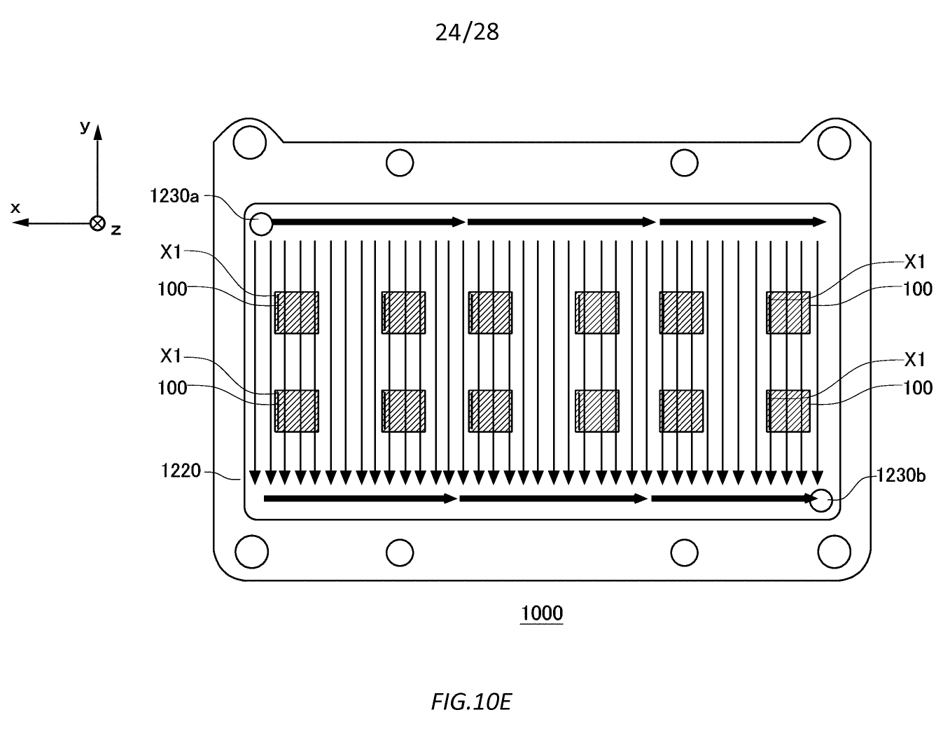

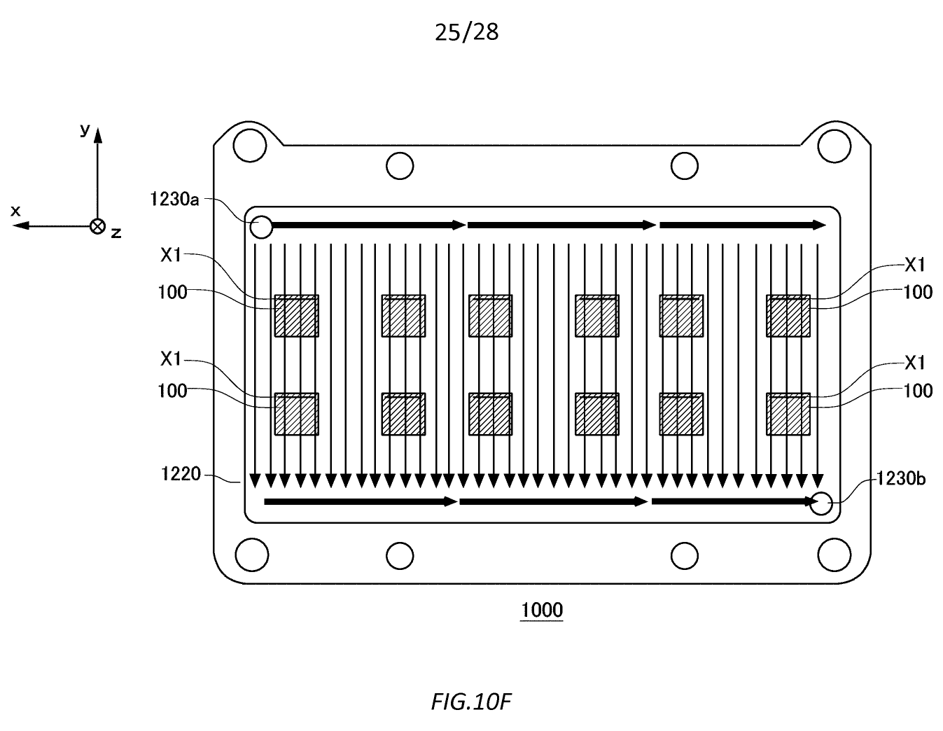

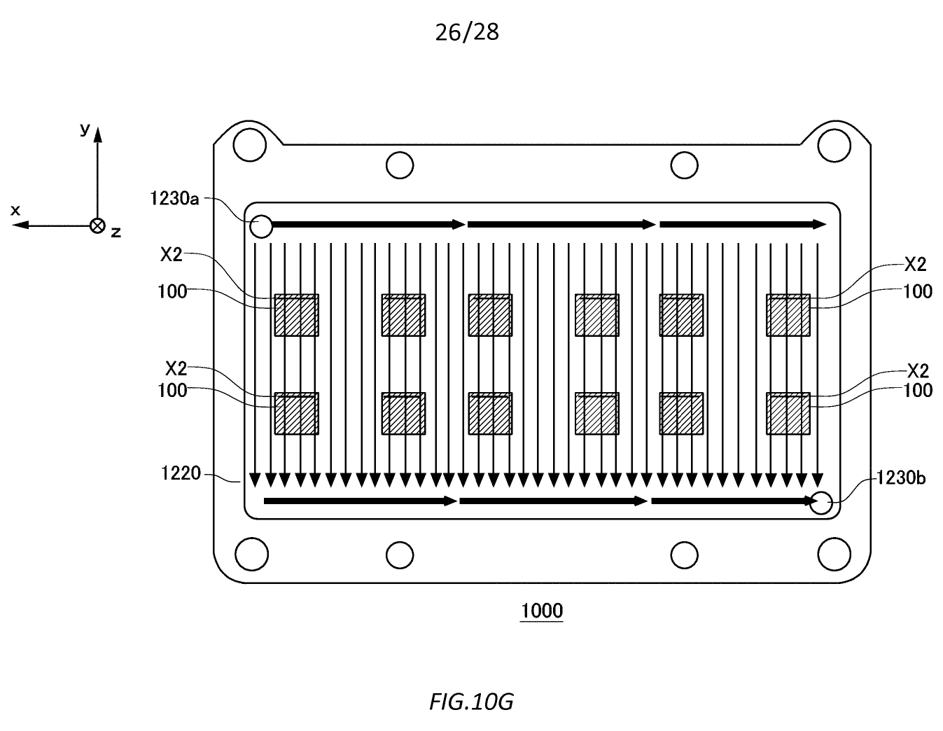

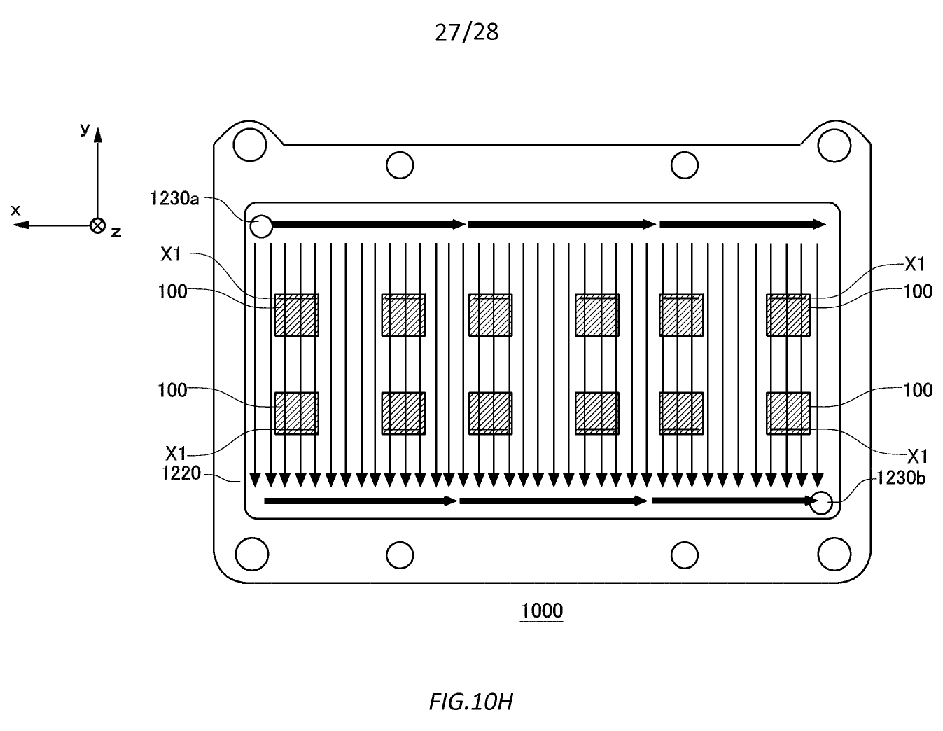

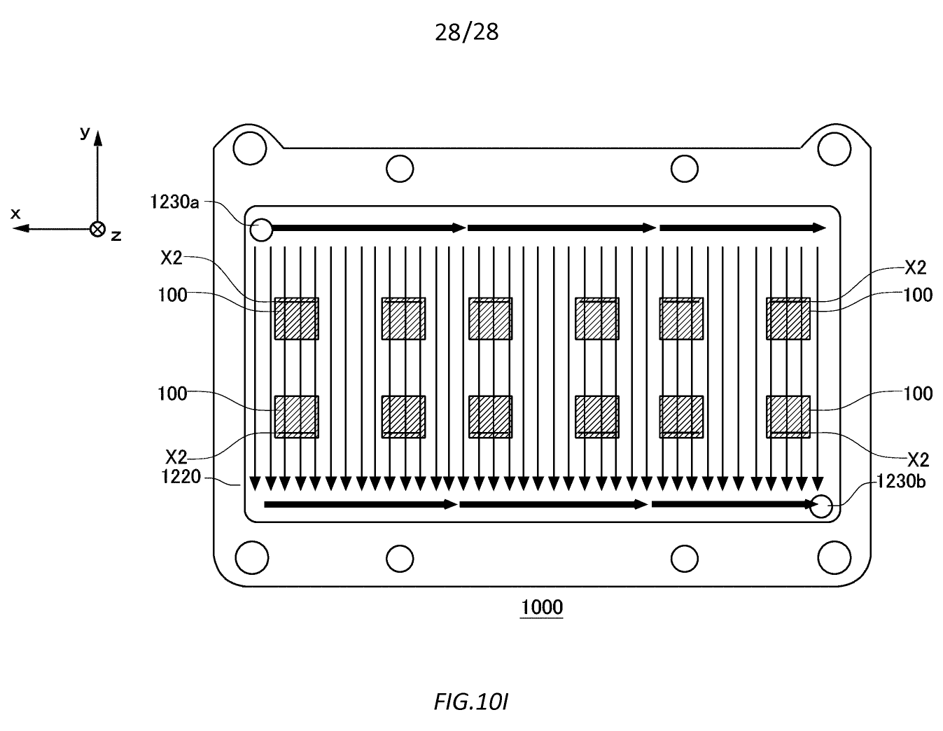

FIG. 10A illustrates an example of a top view of a semiconductor module 1000 according to an embodiment. In a top view of FIG. 10A, a longitudinal direction of a housing 1060 in a rectangular shape is defined as an x axis, and a lateral direction thereof is defined as a y axis. A z axis forms a right-handed system with the x axis and the y axis.

The semiconductor module 1000 includes a heat dissipation base 1010, the housing 1060, and a semiconductor cell 1110. The semiconductor module 1000 of the present example includes three semiconductor cells 1110.

The housing 1060 is a resin terminal case. The housing 1060 defines a region that accommodates the semiconductor cell 1110, and is provided so as to surround the semiconductor cell 1110 in a top view.

A fin-integrated base 1205 has the heat dissipation base 1010 and a cooling fin 1210 described later. The fin-integrated base 1205 has a fin-integrated structure in which the heat dissipation base 1010 and the cooling fin 1210 are integrally formed. In the present specification, the semiconductor module 1000 including the fin-integrated heat dissipation base 1010 is referred to as a fin-integrated semiconductor module. The fin-integrated semiconductor module 1000 can reduce warpage in a finished product by previously warping the fin-integrated heat dissipation base 1010 and performing reflow.

The heat dissipation base 1010 is provided on a lower surface side of the semiconductor module 1000. The heat dissipation base 1010 may be the plate-shaped metal plate having a plane parallel to an xy plane. For example, a material of the heat dissipation base 1010 is a metal material containing aluminum or copper. The heat dissipation base 1010 is provided overlapping with the housing 1060 in a top view.

The semiconductor cell 1110 is mounted on an upper surface of the heat dissipation base 1010. The semiconductor cell 1110 is fixed to the upper surface of the heat dissipation base 1010 by the bonding material such as solder. Thus, heat generated in the semiconductor cell 1110 is transmitted to the heat dissipation base 1010. In the present example, the three semiconductor cells 1110 are disposed side by side in the x axis direction, which is the longitudinal direction, but the present disclosure is not limited to the present example. The semiconductor cell 1110 is an assembly having an insulating substrate 1020 and the semiconductor device 100 of any of FIGS. 1 to 3G and FIGS. 5A to 9. In the present example, four semiconductor devices 100 are provided, as two pairs of two, for each of the three semiconductor cells 1110.

The insulating substrate 1020 is solder-bonded onto the heat dissipation base 1010. The insulating substrate 1020 may be a DCB (Direct Copper Bonding) substrate or an AMB (Active Metal Brazing) substrate. The insulating substrate 1020 has a conductive plate 1021 and an insulating plate 1022.

The insulating plate 1022 is formed of an insulating material such as ceramic. For example, a material of the insulating plate 1022 is alumina (Al₂O₃), aluminum nitride (AlN), or silicon nitride (Si₃N₄).

The conductive plate 1021 is a wiring pattern provided on an upper surface of the insulating plate 1022. For example, a material of the conductive plate 1021 is a metal material such as copper or a copper alloy. The conductive plate 1021 is solder-bonded to the collector electrode 24 of the semiconductor device 100 using, for example, solder. In another example, the conductive plate 1021 and the collector electrode 24 of the semiconductor device 100 may be bonded by pressure bonding. Thus, the conductive plate 1021 is electrically connected to the semiconductor device 100. In the semiconductor cell 1110, the semiconductor device 100, the conductive plate 1021, and a metal wiring board 1040 may be electrically connected to each other so as to constitute a half-bridge circuit.

The metal wiring board 1040 is electrically connected to the semiconductor device 100. For example, the metal wiring board 1040 wires an emitter of the semiconductor device 100. One end of the metal wiring board 1040 may be connected, for example, via solder, to the emitter electrode 52 of the semiconductor device 100. Another end of the metal wiring board 1040 may be connected to the external connection terminal for connection to an outside of the semiconductor module 1000. The metal wiring board 1040 may be a conductive connection member formed by molding a metal plate by press working or the like. The metal plate may be the plate of copper or a copper alloy. The metal wiring board 1040 may have the plating film such as nickel on a surface thereof. A cross section (z-x cross section) of the metal wiring board 1040 may have a rectangular portion. In another example, the metal wiring board 1040 has a wire-like shape, and may be connected to the emitter electrode 52 of the semiconductor device 100 by ultrasonic bonding or the like.

The housing 1060 has a plurality of main terminals 1062. The main terminals 1062 include, for example, a U-phase terminal, a V-phase terminal, and a W-phase terminal for respectively driving a U phase, a V phase, and a W phase in a three-phase inverter circuit. In addition, a main terminal 1062 includes, for example, the power supply terminal for supplying power to a three-phase inverter circuit.

FIG. 10B illustrates an example of an f-f cross section in FIG. 10A. The f-f cross section is an xz cross section passing through the housing 1060 and the semiconductor cell 1110. The semiconductor module 1000 has a cooling unit 1200.

The cooling unit 1200 is disposed below the semiconductor cell 1110. The cooling unit 1200 can be supplied with a refrigerant from outside. The cooling unit 1200 cools the semiconductor module 1000 by passing the refrigerant therethrough. The cooling unit 1200 has the fin-integrated base 1205 and a cooling case 1220. Heat generated by operation of the semiconductor device 100 is released to the outside of the semiconductor module 1000 via the cooling unit 1200 and the refrigerant.

The cooling fin 1210 forms a plurality of flow paths through which a refrigerant is allowed to flow. The cooling fin 1210 is provided extending in the Z axis direction. One end of the cooling fin 1210 on a positive Z axis side is provided connected to a lower surface of the heat dissipation base 1010. One end of the cooling fin 1210 on a negative Z axis side may be in contact with a lower surface of the cooling case 1220. A plurality of cooling fins 1210 are disposed at arbitrary intervals in the X axis direction. The cooling fin 1210 may be, in addition to a straight fin, a wavy fin, a pin fin, a corrugated fin, or a laminated fin. The cooling fin 1210 may be formed of a metal having a same composition as the cooling case 1220. The cooling fin 1210 is formed of, for example, a metal containing aluminum or copper. A material of the cooling fin 1210 may be the metal containing aluminum for weight reduction.

The heat dissipation base 1010 has an integrated structure with the cooling fin 1210. That is, the heat dissipation base 1010 is provided coupled to the cooling fin 1210. In an example, the fin-integrated heat dissipation base 1010 is manufactured by forming fins by machining, brazing, press working, forging, staking, caulking, or the like.

The cooling case 1220 accommodates the cooling fin 1210. The cooling case 1220 covers a lower surface and a side surface of the cooling fin 1210. An upper surface of the cooling fin 1210 is covered with the heat dissipation base 1010. The cooling case 1220 may be formed of a same material as that of the heat dissipation base 1010. The cooling case 1220 may be the box-shaped component having a bottom plate and side walls. The cooling case 1220 may have a flange connected to the side wall. The flange can be bonded to the heat dissipation base 1010.

The insulating substrate 1020 is solder-bonded to the heat dissipation base 1010 by an under-substrate solder portion 1025. The insulating substrate 1020 includes the conductive plate 1021, the insulating plate 1022, and a conductive plate 1023.

The conductive plate 1023 is provided on a lower surface of the insulating plate 1022. The conductive plate 1021 and the conductive plate 1023 are formed of, for example, a conductive material such as copper or a copper alloy, or a metal material. The conductive plate 1023 is provided over substantially the entire lower surface of the insulating plate 1022.

An encapsulation resin 1050 encapsulates an inside of the housing 1060. The encapsulation resin 1050 covers a periphery of the semiconductor cell 1110. The material of the encapsulation resin 1050 may be either the epoxy resin or the silicone gel. A lower surface of the encapsulation resin 1050 may be provided in contact with the upper surface of the heat dissipation base 1010. A side surface of the encapsulation resin 1050 may be provided in contact with the housing 1060. An upper surface of the encapsulation resin 1050 is provided below an upper surface of the housing 1060.

The cooling case 1220 and the cooling fin 1210 may be formed by press working, forging, or extrusion process. The cooling case 1220 and the cooling fin 1210 may be assembled by brazing process. A brazing material may be formed of a metal having a melting point lower than that of the cooling case 1220. As the brazing material, a metal containing copper or aluminum may be used as a low-melting-point metal.

FIG. 10C is an example of a bottom view of the semiconductor module 1000. At a lower surface of the semiconductor module 1000, the heat dissipation base 1010 is provided with an opening 1016 for attaching a step jig.

The cooling fins 1210 extend along the y axis direction and are provided side by side in the x axis direction within the cooling case 1220. In the present example, the cooling fin 1210 is a straight fin having a strip shape with the y axis direction as a longitudinal direction. The number and shape of the cooling fins 1210 are not limited to those of the present example.

A refrigerant flow portion 1230 is provided on the lower surface of the cooling case 1220. The refrigerant flow portion 1230 allows a refrigerant to flow through an inside of the cooling case 1220. In an example, the refrigerant flows into the cooling case 1220 through a refrigerant flow portion 1230a and flows out of the cooling case 1220 through a refrigerant flow portion 1230b. In FIG. 10C, the refrigerant flow portion 1230a and the refrigerant flow portion 1230b are provided at end portions of the cooling case 1220 in the longitudinal direction, but the present disclosure is not limited thereto. The refrigerant flow portion 1230a and the refrigerant flow portion 1230b may be provided near the middle, or may be provided in accordance with a configuration of the semiconductor device 100.

FIG. 10D illustrates an example of a g-g cross section in FIG. 10C. The g-g cross section is an xz cross section passing through the refrigerant flow portion 1230a. The refrigerant flow portion 1230 includes the refrigerant flow portion 1230a and the refrigerant flow portion 1230b.

The refrigerant flow portion 1230a is coupled to an external device or the like and causes a refrigerant to flow into the cooling case 1220. The refrigerant flow portion 1230ais provided with an opening 232a for causing the refrigerant to flow in.

The refrigerant flow portion 1230b is coupled to an external device or the like and causes the refrigerant to flow out of the cooling case 1220. The refrigerant flow portion 1230b is provided with an opening 232b for causing the refrigerant to flow out. The refrigerant may circulate between the external device and the cooling unit 1200.

The refrigerant flow portion 1230 has a structure protruding from the lower surface of the cooling case 1220. The refrigerant flow portion 1230 may have the flange or a pipe for connection to an external device. The refrigerant flow portion 1230 is manufactured such that its angle matches that of an opening of an external device in order to be inserted into the opening of the external device.

FIG. 10E is a schematic diagram illustrating a placement of the semiconductor device 100 in the semiconductor module 1000. The cooling unit 1200 of the present example causes a refrigerant to flow so as to cool the semiconductor device 100 from a positive Y axis side. Arrows illustrated in FIG. 10E indicate an example of a flow path of the refrigerant. The refrigerant is illustrated as flowing along the cooling fin 1210 illustrated in FIG. 10C from the positive side to the negative side in the y axis direction. A flow path from the refrigerant flow portion 1230a to the refrigerant flow portion 1230b may be configured such that the positive Y axis side of the first active portion 160 is on an upstream side. That is, in the present example, each semiconductor device 100 may be disposed such that the first end portion X1 side thereof is on a positive x axis side. In another example, each semiconductor device 100 may be disposed such that the first end portion X1 side thereof is on a negative x axis side, and the flow path from the refrigerant flow portion 1230a to the refrigerant flow portion 1230b may be configured such that a negative Y axis side of the first active portion 160 is on the upstream side.

FIG. 10F is a schematic diagram illustrating a different placement of the semiconductor device 100 in the semiconductor module 1000. The cooling unit 1200 of the present example causes a refrigerant to flow so as to cool the semiconductor device 100 from the first end portion X1 side of the first active portion 160. A flow path from the refrigerant flow portion 1230ato the refrigerant flow portion 1230b may be configured such that the first end portion X1 side of the first active portion 160 is on the upstream side. That is, in the present example, each semiconductor device 100 may be disposed such that the first end portion X1 side thereof is on the positive y axis side. Thus, by cooling the semiconductor device 100 from the first end portion X1 side to which the first diode portion 80-1 is close, it is possible to suppress a temperature rise of each diode portion 80, particularly a temperature rise of each first diode portion 80-1.

FIG. 10G is a schematic diagram illustrating a different placement of the semiconductor device 100 in the semiconductor module 1000. The cooling unit 1200 of the present example causes a refrigerant to flow so as to cool the semiconductor device 100 from the second end portion X2 side of the first active portion 160. A flow path from the refrigerant flow portion 1230ato the refrigerant flow portion 1230b may be configured such that the second end portion X2 side of the first active portion 160 is on the upstream side. That is, in the present example, each semiconductor device 100 may be disposed such that the second end portion X2 side thereof is on the positive y axis side. In the semiconductor device 100 of the present example, the second transistor portion 70-2 is provided on the second end portion X2 side. Thus, by cooling the semiconductor device 100 from the second end portion X2 side to which the second transistor portion 70-2 is close, it is possible to suppress a temperature rise of each transistor portion 70, particularly a temperature rise of each second transistor portion 70-2.

FIG. 10H is a schematic diagram illustrating a different placement of the semiconductor device 100 in the semiconductor module 1000. The present example differs from the example illustrated in FIG. 10F in that the first end portion X1 side of each semiconductor device 100 disposed on the negative y axis side is disposed so as to be on the negative y axis side. In FIG. 10F, the semiconductor device 100 placed on the positive y axis side is disposed such that the first end portion X1 side, to which the first diode portion 80-1 is close, is farther from an adjacent semiconductor device 100 in the y axis direction, whereas in FIG. 10H, the semiconductor device 100 placed on the negative y axis side is also disposed such that the first end portion X1 side, to which the first diode portion 80-1 is close, is farther from an adjacent semiconductor device 100 in the y axis direction. Thus, by placement such that the first end portion X1 side, to which the first diode portion 80-1 is close, is farther from another adjacent semiconductor device, it is possible to suppress the temperature rise of each first diode portion 80-1. The first end portion X1 of the semiconductor device 100 disposed on the outermost positive side or negative side in the x axis direction may be disposed so as to face outward (toward the positive side or the negative side) in the x axis direction.

FIG. 10I is a schematic diagram illustrating a different placement of the semiconductor device 100 in the semiconductor module 1000. The present example differs from the example illustrated in FIG. 10G in that the second end portion X2 side of each semiconductor device 100 disposed on the negative y axis side is disposed so as to be on the negative y axis side. In FIG. 10G, the semiconductor device 100 disposed on the positive y axis side is disposed such that the second end portion X2 side, to which the second transistor portion 70-2 is close, is farther from an adjacent semiconductor device 100 in the y axis direction. In contrast, in FIG. 10I, the semiconductor device 100 disposed on the negative y axis side is also disposed such that the second end portion X2 side, to which the second transistor portion 70-2 is close, is farther from an adjacent semiconductor device 100 in the y axis direction. Thus, by placement such that the second end portion X2 side, to which the second transistor portion 70-2 is close, is farther from another adjacent semiconductor device, the temperature rise of each second transistor portion 70-2 can be suppressed. Note that the second end portion X2 of the semiconductor device 100 disposed on the outermost positive side or negative side in the x axis direction may be disposed so as to face outward (toward the positive side or the negative side) in the x axis direction.

The semiconductor devices 100 in the placement illustrated in FIGS. 10E, 10F, and 10H are not limited to those of the examples illustrated in FIGS. 1 and 5A, and those of the examples illustrated in FIGS. 5B -5D and FIGS. 6 -7B may also be applied. The semiconductor devices 100 in the placement illustrated in FIGS. 10G and 10I are not limited to those of the examples illustrated in FIGS. 1 and 5A, and those of the examples illustrated in FIGS. 6 -7B may also be applied. In addition, in the above examples, the semiconductor module 1000 has been described in a form in which the cooling unit 1200, having cooling fins 1210 and a predetermined refrigerant flow path, is integrated with a portion in which the semiconductor device 100 is wired; however, in the present invention, a single or a plurality of packages, in which a single or a plurality of semiconductor devices 100 are wired and which are disposed on a separately prepared cooler, may also be treated as a semiconductor module.

As described above, the present invention has been described using embodiments, but the technical scope of the present invention is not limited to the scope described in the above-described embodiments. It is apparent to those skilled in the art that various modifications or improvements can be made to the above-described embodiments. It is apparent from the description of the claims that embodiments to which such modifications or improvements are made may also be included in the technical scope of the present invention.

It should be noted that an execution order of respective processes such as operations, procedures, steps, and stages in a device, a system, a program, and a method shown in the claims, the specification, and the drawings can be realized in any order unless "before", "prior to", and the like are explicitly stated in particular, and unless an output of a previous processing is used in a subsequent processing. Even if, for convenience, an operation flow in the claims, the specification, and the drawings is described using "first", "next", and the like, this does not mean that performing in this order is essential.

### EXPLANATION OF REFERENCES

10: semiconductor substrate, 11: well region, 12: emitter region, 14: base region, 15: contact region, 16: accumulation region, 18: drift region, 20: buffer region, 21: front surface, 22: collector region, 23: back surface, 24: collector electrode, 25: connection portion, 29: extending portion, 30: dummy trench portion, 31: connecting portion, 32: dummy dielectric film, 34: dummy conductive portion, 38: interlayer dielectric film, 40: gate trench portion, 39: extending portion, 42: gate dielectric film, 41: connecting portion, 44: gate conductive portion, 47: outer peripheral gate runner, 48: semiconductor gate runner, 49: boundary, 50: gate metal layer, 52: emitter electrode, 54: contact hole, 55: contact hole, 56: contact hole, 57: contact hole, 60: mesa portion, 70: transistor portion, 72: lifetime control region, 80: diode portion, 82: cathode region, 84: resistor portion, 90: transition region, 91: boundary region, 92: guard ring, 93: outer edge portion, 94: field plate, 100: semiconductor device, 102: end side, 160: first active portion, 161: second active portion, 190: outer peripheral region, 210: current sense portion, 260: first active portion, 1000: semiconductor module, 1010: heat dissipation base, 1016: opening, 1020: insulating substrate, 1021: conductive plate, 1022: insulating plate, 1023: conductive plate, 1025: under-substrate solder portion, 1040: metal wiring board, 1050: encapsulation resin, 1060: housing, 1062: main terminal, 1110: semiconductor cell, 1200: cooling unit, 1205: fin-integrated base, 1210: cooling fin, 1220: cooling case, 1230: refrigerant flow portion.

What is claimed is:

1. A semiconductor device comprising a first active portion having a plurality of transistor portions and a plurality of diode portions alternately arranged in an arrangement direction, the semiconductor device comprising:
a drift region of a first conductivity type provided in a semiconductor substrate;
a plurality of trench portions extending in a predetermined trench extending direction on a front surface of the semiconductor substrate;
a base region of a second conductivity type provided above the drift region;
an emitter region of the first conductivity type provided on the front surface of the semiconductor substrate and having a doping concentration higher than that of the drift region;
a contact region of the second conductivity type provided above the drift region and having a doping concentration higher than that of the base region; and
a lifetime control region provided closer to a front surface side of the semiconductor substrate than a center in a depth direction of the semiconductor substrate, wherein
the first active portion has, in the arrangement direction, a first end portion and a second end portion on an opposite side to the first end portion,
the plurality of diode portions have a first diode portion provided closest to the first end portion and a second diode portion provided closest to the second end portion,
the plurality of transistor portions have a first transistor portion provided closest to the first end portion and a second transistor portion provided closest to the second end portion, and
the first diode portion is provided closer to a first end portion side than the first transistor portion.

2. The semiconductor device according to claim 1, wherein the second transistor portion is provided closer to the second end portion side than the second diode portion.

3. The semiconductor device according to claim 1, wherein the second diode portion is provided closer to the second end portion side than the second transistor portion.

4. The semiconductor device according to claim 3, wherein, on the front surface of the semiconductor substrate, areas of the first diode portion and the second diode portion are different from areas of other diode portions.

5. The semiconductor device according to claim 3, wherein, on the front surface of the semiconductor substrate, areas of the first diode portion and the second diode portion are smaller than areas of other diode portions.

6. The semiconductor device according to claim 3, wherein, on the front surface of the semiconductor substrate, areas of the first diode portion and the second diode portion are larger than areas of other diode portions.

7. The semiconductor device according to claim 1, comprising a second active portion separated from the first active portion in a direction orthogonal to the arrangement direction and having the plurality of transistor portions and the plurality of diode portions alternately arranged in the arrangement direction, wherein
the second active portion has, in the arrangement direction, a third end portion and a fourth end portion on an opposite side to the third end portion, the third end portion is adjacent to the first end portion in an extending direction of the plurality of transistor portions and the plurality of diode portions, and the fourth end portion is adjacent to the second end portion in the extending direction,
the plurality of diode portions in the second active portion have a third diode portion provided closest to the third end portion and a fourth diode portion provided closest to the fourth end portion,
the plurality of transistor portions in the second active portion have a third transistor portion provided closest to the third end portion and a fourth transistor portion provided closest to the fourth end portion, and
an arrangement of the plurality of transistor portions and the plurality of diode portions in the second active portion is different from an arrangement of the plurality of transistor portions and the plurality of diode portions in the first active portion.

8. The semiconductor device according to claim 7, wherein the fourth diode portion is provided closer to the fourth end portion side than the fourth transistor portion.

9. The semiconductor device according to claim 7, wherein
each transistor portion has a transition region provided on an adjacent diode portion side, and
a number of at least one transition region in the first active portion is equal to a number of at least one transition region in the second active portion.

10. The semiconductor device according to claim 7, wherein
a plurality of first active portions are provided,
in the first active portion, the second diode portion is provided closer to the second end portion side than the second transistor portion, and
in the second active portion, the third transistor portion is provided closer to the third end portion side than the third diode portion, and the fourth transistor portion is provided closer to the fourth end portion side than the fourth diode portion.

11. The semiconductor device according to claim 10, wherein
each transistor portion has a transition region provided on an adjacent diode portion side, and
a number of at least one transition region in the first active portion is equal to a number of at least one transition region in the second active portion.

12. The semiconductor device according to claim 1, comprising:
a well region of the second conductivity type provided on the front surface of the semiconductor substrate in an outer peripheral region surrounding the first active portion and having a doping concentration higher than that of the base region; and
a cathode region of the first conductivity type provided in each diode portion on a back surface of the semiconductor substrate and having a doping concentration higher than that of the drift region, wherein
in the arrangement direction, an outer end portion of the cathode region of the first diode portion is located on an inner side of an inner end portion of the well region.

13. The semiconductor device according to claim 1, comprising:
an interlayer dielectric film provided above the front surface of the semiconductor substrate and having a plurality of contact holes;
an emitter electrode provided above the interlayer dielectric film;
a well region of the second conductivity type provided on the front surface of the semiconductor substrate in an outer peripheral region surrounding the first active portion and having a doping concentration higher than that of the base region; and
a cathode region of the first conductivity type provided in each diode portion on a back surface of the semiconductor substrate and having a doping concentration higher than that of the drift region, wherein
the emitter electrode is connected, through the plurality of contact holes, to the front surface of the semiconductor substrate in the first active portion and the well region, and
the semiconductor device has a resistor portion provided from an outer end portion of the well region to a contact hole provided outermost among the plurality of contact holes.

14. The semiconductor device according to claim 13, wherein the resistor portion has at least one trench portion of the plurality of trench portions.

15. The semiconductor device according to claim 1, comprising:
a well region of the second conductivity type provided on the front surface of the semiconductor substrate in an outer peripheral region surrounding the first active portion and having a doping concentration higher than that of the base region; and
a cathode region of the first conductivity type provided in each diode portion on a back surface of the semiconductor substrate and having a doping concentration higher than that of the drift region, wherein
the lifetime control region is provided extending, in the arrangement direction, from the first diode portion to at least a part of the outer peripheral region.

16. A semiconductor module comprising:
the semiconductor device according to claim 1; and
a cooling unit which cools the semiconductor device from the first end portion side.

17. A semiconductor module comprising:
the semiconductor device according to claim 1; and
another semiconductor device, wherein
the semiconductor device is disposed such that the first end portion side of the semiconductor device does not face the another semiconductor device.

18. A semiconductor module comprising:
the semiconductor device according to claim 2; and
a cooling unit which cools the semiconductor device from the second end portion side.

19. A semiconductor module comprising:
the semiconductor device according to claim 2; and
another semiconductor device, wherein
the semiconductor device is disposed such that the second end portion side of the semiconductor device does not face the another semiconductor device.

20. A semiconductor module comprising:
the semiconductor device according to claim 7; and
another semiconductor device, wherein
the semiconductor device is disposed such that the second end portion side of the semiconductor device does not face the another semiconductor device.
